(19) United States
(12) Patent Application Publication
(10) Pub. No.: US 2026/0282918 A1
(43) Pub. Date: Sep. 17, 2026

(54) SEMICONDUCTOR STRUCTURE INCLUDING A GUARD RING AND METHODS FOR FORMING THE SAME

(71) Applicant: Taiwan Semiconductor Manufacturing Company Limited, Hsinchu (TW)

(72) Inventor: Tzuan-Horng Liu, Longtan Township (TW)

(21) Appl. No.: 19/078,348

(22) Filed: Mar. 13, 2025

(51) Int. Cl. H01L 23/00; H01L 23/31; H01L 23/40; H01L 23/538; H01L 25/00; H01L 25/18

(52) U.S. Cl. CPC H10W 42/121; H10W 40/611; H10W 70/611; H10W 70/65; H10W 90/00; H10W 90/401; H10W 74/111

(57) ABSTRACT

A semiconductor structure includes a lower redistribution layer (RDL) structure, a lower molded portion including an interconnect die on the lower RDL structure, an upper RDL structure on the lower molded portion, and a guard ring including a lower RDL portion in the lower RDL structure, a lower via portion in the lower molded portion, and an upper RDL portion in the upper RDL structure.

### BACKGROUND

In semiconductor device manufacturing, a fastening member (e.g., screw, bolt, etc.) may be used to fix a semiconductor structure to another structure such as a printed circuit board (PCB). The fastening member may be inserted in a fastening hole in the semiconductor structure. In some cases, a guard ring may be formed in the semiconductor structure around the fastening hole. The guard ring may help to enhance the mechanical, thermal, and electrical reliability of the semiconductor structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top-down view of a semiconductor structure according to one or more embodiments.

FIG. 1B is a top-down view of Region R1 of the semiconductor structure in FIG. 1A according to one or more embodiments.

FIG. 1C is a vertical cross-sectional view of the portion of the semiconductor structure according to one or more embodiments.

FIG. 1D is a vertical cross-sectional view of a semiconductor die unit in the semiconductor structure according to one or more embodiments.

FIG. 2 is a vertical cross-sectional view of an SoP structure according to one or more embodiments.

FIG. 3A is a top-down view of Region R2 of the semiconductor structure in FIG. 1A according to one or more embodiments.

FIG. 3B is a vertical cross-sectional view of the portion of the semiconductor structure according to one or more embodiments.

FIG. 3C is a vertical cross-sectional view of a semiconductor die unit in the semiconductor structure according to one or more embodiments.

FIG. 4A is a vertical cross-sectional view of the region R3 in FIG. 3B according to one or more embodiments.

FIG. 4B is a top-down view of the guard ring along line C-C′ in FIG. 4A according to one or more embodiments.

FIG. 4C is a top-down view of the guard ring along line D-D′ in FIG. 4A according to one or more embodiments.

FIG. 5A is a vertical cross-sectional view of each of the SoC die and the interconnect die on a frame mount according to one or more embodiments.

FIG. 5B is a vertical cross-sectional view of an intermediate structure including the lower RDL structure on a first carrier substrate according to one or more embodiments.

FIG. 5C is a vertical cross-sectional view of an intermediate structure including the TIVs according to one or more embodiments.

FIG. 5D is a vertical cross-sectional view of an intermediate structure including the interconnect die mounted on the lower RDL structure according to one or more embodiments.

FIG. 5E is a vertical cross-sectional view of an intermediate structure including the lower molding material layer according to one or more embodiments.

FIG. 5F is a vertical cross-sectional view of an intermediate structure including the upper RDL structure according to one or more embodiments.

FIG. 5G is a vertical cross-sectional view of an intermediate structure including the semiconductor dies on the upper RDL structure according to one or more embodiments.

FIG. 5H is a vertical cross-sectional view of an intermediate structure including the semiconductor die underfill layer according to one or more embodiments.

FIG. 5I is a vertical cross-sectional view of an intermediate structure including the upper molding material layer according to one or more embodiments.

FIG. 5J is a vertical cross-sectional view of an intermediate structure including the BGA according to one or more embodiments.

FIG. 5K is a vertical cross-sectional view of an intermediate structure including the fastening holes in the semiconductor structure according to one or more embodiments.

FIG. 6 is a flow chart illustrating a method of making the semiconductor structure according to one or more embodiments.

FIG. 7A is a vertical cross-sectional view of the semiconductor structure including the guard ring having the first alternative configuration according to one or more embodiments.

FIG. 7B is a detailed vertical cross-sectional view of the guard ring having the first alternative configuration according to one or more embodiments.

FIG. 8 is a top-down view of the guard ring having a second alternative configuration according to one or more embodiments.

FIG. 9 is a top-down view of the guard ring having a third alternative configuration according to one or more embodiments.

FIG. 10 is a top-down view of the guard ring having a fourth alternative configuration according to one or more embodiments.

FIG. 11 is a vertical cross-sectional view of the semiconductor die unit having a first alternative configuration according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various semiconductor assemblies may utilize a fastening device in order to fasten or affix structures such as a thermal plate or lid to a stacked semiconductor structure. For example, a system-on-panel (SoP) structure is an advanced semiconductor integration and packaging concept in which a system-level functionality, typically implemented on a system-on-chip (SoC) or system-in-package (SiP), is realized directly on a large panel substrate instead of on a traditional wafer or package substrate. The SoP structure may leverage the benefits of panel-level manufacturing to achieve cost efficiency, scalability, and integration for various electronic applications.

Unlike traditional silicon wafers, the SoP structure may use large rectangular or square panel substrates, typically made from materials such as glass, organic laminates, or flexible plastics. These panels can be much larger than wafers (e.g., sizes of 510 mm×515 mm or more), enabling higher throughput and lower cost per unit.

The SoP structure may be used, for example, in large-area electronics, such as displays (e.g., OLED, microLED), sensors and imaging systems, Internet-of-things (IoT) devices and smart surfaces, and automotive displays and control panels. The SoP structure may integrate multiple components, such as logic circuits (e.g., CPUs, GPUs), memory (DRAM, Flash), power management units (PMUs), sensors (e.g., photodetectors, touch sensors) and communication interfaces (e.g., RF modules, antennas). These components may be co-designed and fabricated on or embedded into the panel.

The SoP structure may provide for heterogeneous integration of multiple technologies, including, for example, thin-film transistors (TFTs), active and passive devices, and optical, mechanical, and power components. The SoP structure may also allow for high-density interconnects by using sophisticated redistribution layers (RDLs) to interconnect the components on the panel. The SoP may also use advanced bonding techniques like hybrid bonding, microbump interconnects, or direct metal bonding. Since panel-level manufacturing may reduce the cost per die/unit by processing more devices in parallel, the SoP structure may help to reduce costs. The SoP structure may also provide scalability because larger panels may allow for higher production throughput compared to wafer-based manufacturing.

The SoP structure may be fabricated on thin substrates, making it ideal for flexible and lightweight applications. The SoP structure may also enable the integration of diverse components on a single platform, reducing the need for multiple separate devices or modules. The large panel area of the SoP structure may support custom designs for specific applications, such as curved displays or flexible electronics.

In some embodiments, the fastening hole may be formed in an RDL structure of the semiconductor structure to accommodate the fastening member used to affix or fasten structures to the stacked semiconductor structure. In such embodiments, the formation of the fastening hole may cause peeling of one or more materials (e.g., passivation material) of the RDL structure. The fastening hole may also cause formation of a crack in a redistribution layer of an RDL structure. In some instances, the crack may extend into an active area of the RDL structure. The peeling and crack formation in the RDL structure may also be exacerbated by the insertion of the fastening member in the fastening hole and the mechanical stresses applied by the fastening member to the RDL structure over time. Thus, the SoP structure may benefit from the use of a guard ring. The SoP structure may include the semiconductor structure with the guard ring around the fastening hole. In some embodiments, a guard ring may be formed in the semiconductor structure around the fastening hole in which the fastening member is inserted. The guard ring may help to enhance the mechanical, thermal, and electrical reliability of the semiconductor structure.

The guard ring may include a raised or recessed circular feature in the material (e.g., molding material, organic polymer, etc.) that surrounds the fastening hole where the fastening member is inserted. The guard ring may be made of metal, ceramic, polymer material, etc. The guard ring may be coated with a protective layer or embedded with fillers to enhance mechanical strength and thermal stability. The dimensions of the guard ring, such as its thickness and width, may be carefully designed to ensure optimal performance based on the requirements of the semiconductor device.

At least one embodiment of the present disclosure may include a semiconductor structure with an improved guard ring that may help to improve a strength of the fastening hole and the material surrounding the fastening hole. The improved guard ring may help to avoid peeling of the materials of the RDL structure and avoid formation of a crack in the active area of the RDL structure.

Various embodiment improved guard rings may enhance a strength of a fastening hole in a semiconductor structure of an SoP structure. The SoP structure may include a panel (e.g., glass panel) having a size, for example, in a range from 100 mm×100 mm to 1000 mm×1000 mm (e.g., about 510 mm×515 mm). The semiconductor structure may include a plurality of semiconductor die units (e.g., semiconductor die sets) arranged in an array having a plurality of rows and columns. Each semiconductor die unit may include, for example, one or more SoC dies, one or more high bandwidth memory (HBM) dies and one or more input/output (I/O) dies. The number of semiconductor die units on the panel may be in a range from 10 to 150. In at least one embodiment, the panel may include about 80 semiconductor die units in an 8×10 array (row×column) array.

In at least one embodiment, the fastening hole in the semiconductor structure may be formed by a laser drill. The fastening hole may have a diameter, for example, in a range from 1 mm to 8 mm (e.g., about 4 mm to 5 mm). In at least one embodiment, the guard ring may be formed of a metal such as copper. In at least one embodiment, the guard ring may be formed of the same material as the metal layers and metal vias in the RDL structure. In at least one embodiment, the guard ring may be formed by the same process used to form the metal layers and metal vias in the RDL structure.

The SoP may include a frame including a plurality of ribs attached to the PCB. The semiconductor structure may be pressed onto the PCB. The PCB may help to eliminate stresses on the semiconductor substrate. A thermal interface material (TIM) layer may be placed on the semiconductor die units of the semiconductor structure. A thermal plate (e.g., cold plate) may be attached to the semiconductor structure through the TIM layer.

The fastening hole may be formed simultaneously in the semiconductor structure, the PCB and the thermal plate. Alternatively or additionally, the forming of the fastening holes in the semiconductor structure, the forming of the fastening holes in the PCB and the forming of the fastening holes in the thermal plate may be performed separately. In such embodiments, the fastening holes in the semiconductor structure, the fastening holes in the PCB and the fastening holes in the thermal plate may be aligned at the time of assembly.

The fastening member may be inserted into the fastening hole of the thermal plate, the fastening hole of the semiconductor structure and the fastening hole of the PCB. The fastening member may fasten together the components of the SoP structure (e.g., thermal plate, semiconductor structure, PCB and frame (e.g., ribs). The fastening member may help to balance the forces applied to the SoP and in particular, the forces applied to the semiconductor structure.

The fastening member may extend from one side of the assembly (e.g., a side of the thermal plate) and out of the opposing side of the assembly (e.g., a side of the PCB). The fastening member may be pulled out of the opposing side so that a threaded portion of the fastening member extends out of the fastening hole on the opposing side by at least 5 mm. In at least one embodiment, the fastening member may be inserted into the fastening hole of the thermal plate and pulled out of the fastening hole in the PCB so that a threaded portion of the fastening member extends out of the fastening hole of the PCB by at least 5 mm. This may allow at least 5 mm of the threaded portion of the fastening member may be engaged with the internal threads of the ribs. This may help to ensure that the semiconductor structure and thermal plate are firmly fixed the PCB.

The semiconductor structure may include a lower RDL structure (backside RDL), a lower molded portion on the lower RDL structure and an upper RDL structure (frontside RDL or middle RDL) on the lower molded portion. The semiconductor structure may also include an upper molded portion including a plurality of semiconductor dies on the upper RDL portion. The lower molded portion may include an interconnect die attached to the lower RDL structure, for example, by fine pitch microbumps. The interconnect die may have a frontside-to-frontside (F2F) configuration (e.g., a frontside of the semiconductor dies faces a frontside of the interconnect die) or a frontside-to-backside (F2B) configuration (e.g., a frontside of the semiconductor dies faces a backside of the interconnect die) on the lower RDL structure. The lower RDL structure and upper RDL structure may provide a more uniform distribution of through silicon vias (TSVs) in the interconnect die and may also provide a more robust power distribution.

Various embodiment guard rings (e.g., stacked die guard ring) may include a lower RDL portion in the lower RDL structure and an upper RDL portion in the upper RDL portion. Further, in contrast to other related guard rings, various embodiment guard rings may include a lower TIV portion in the lower molded portion. The lower TIV portion may be located between the lower RDL portion and the upper RDL portion of the guard ring. The lower TIV portion may include a plurality of metal vias arranged in a ring around the fastening hole. The lower TIV portion may alternatively or additionally include an annular-shaped metal via around the fastening hole. The lower TIV portion may alternatively or additionally include a segmented annular-shaped metal via around the fastening hole.

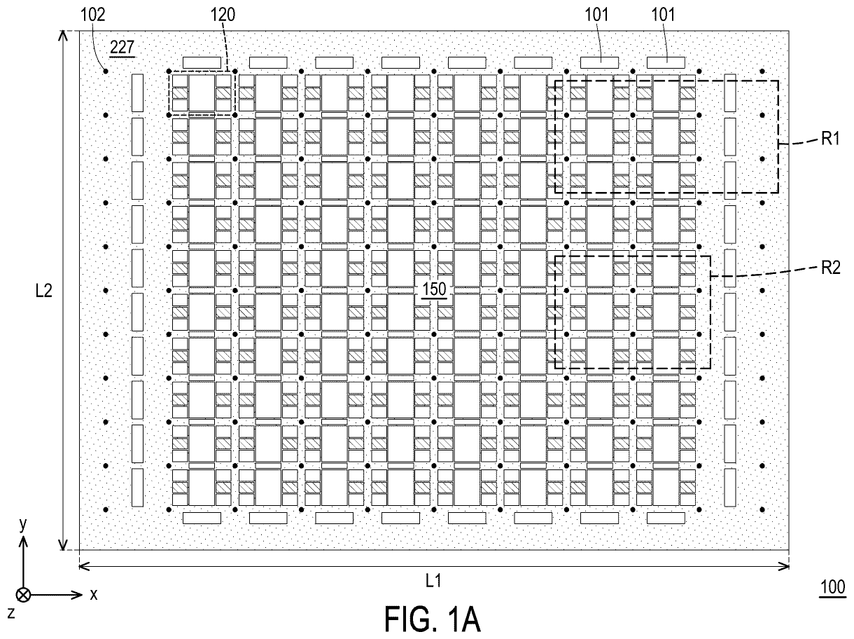

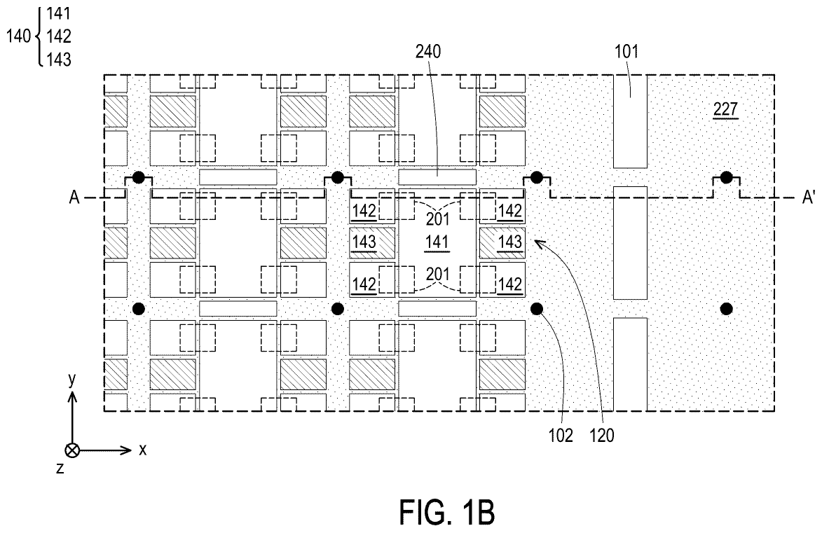

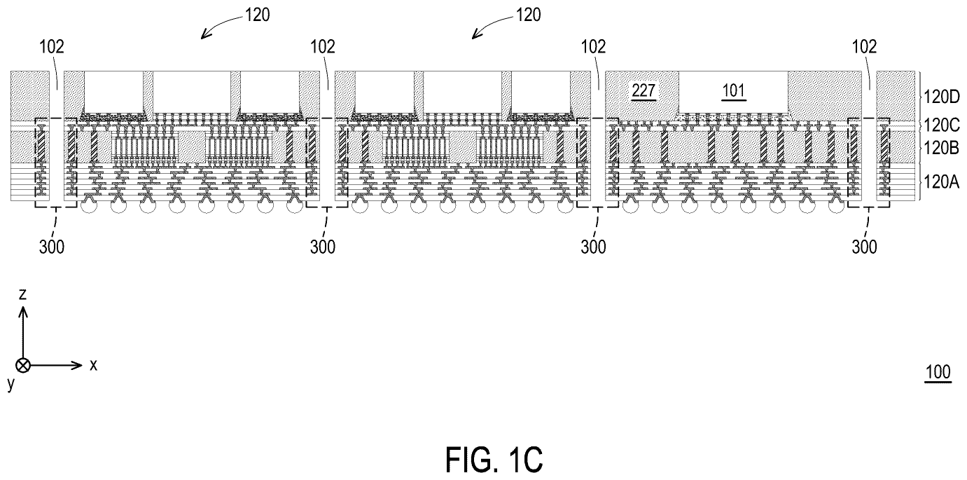

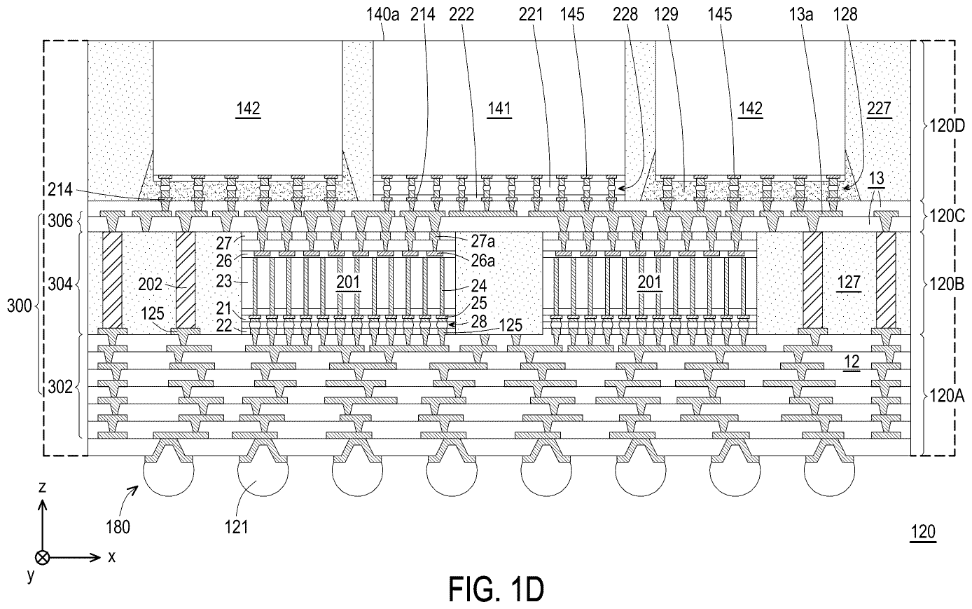

FIG. 1A is a top-down view of a semiconductor structure 100 according to one or more embodiments. FIG. 1B is a top-down view of Region R1 of the semiconductor structure 100 in FIG. 1A according to one or more embodiments. FIG. 1C is a vertical cross-sectional view of the portion of the semiconductor structure 100 according to one or more embodiments. The vertical cross-sectional view in FIG. 1C is along the line A-A′ in FIG. 1B. FIG. 1D is a vertical cross-sectional view of a semiconductor die unit 120 in the semiconductor structure 100 according to one or more embodiments.

As illustrated in FIG. 1A, the semiconductor structure 100 may have a substantially square shape or substantially rectangular shape. Other shapes are within the contemplated scope of disclosure. The semiconductor structure 100 may have a length L1 in the x-direction in a range from 100 mm to 1000 mm (e.g., about 510 mm). The semiconductor structure 100 may have a length L2 in the y-direction in a range from 100 mm to 1000 mm (e.g., about 515 mm). In at least one embodiment, the length of the semiconductor structure 100 in the y-direction may be greater than the length of the semiconductor structure 100 in the x-direction. In at least one embodiment, the length of the semiconductor structure 100 in the x-direction may be greater than the length of the semiconductor structure 100 in the y-direction.

The semiconductor structure 100 may include an upper molding material layer 227. The upper molding material layer 227 may include, for example, epoxy molding compound (EMC). In at least one embodiment, the upper molding material layer 227 may include a polymeric material and in particular, an epoxy-based polymeric material. Other suitable molding materials may be used.

The semiconductor structure 100 may also include an array 150 including a plurality of semiconductor die units 120 in the upper molding material layer 227. The semiconductor die units 120 may include a plurality of semiconductor dies. The plurality of semiconductor dies may include, for example, one or more primary dies and one or more secondary dies on one or more sides of the primary die in the x-direction. The array 150 may include a plurality of rows of the semiconductor die units 120 extending lengthwise in the x-direction (row direction) and a plurality of columns of the semiconductor die units 120 extending lengthwise in the y-direction (column direction). The array 150 is illustrated in FIG. 1A as an 8×10 array (e.g., 8 semiconductor die units 120 per row and 10 semiconductor die units 120 per column). However, the array 150 may include any number of rows and columns and any number of semiconductor die units 120 in the rows and columns. In at least one embodiment, the number of semiconductor die units 120 may be in a range from 10 to 150.

The semiconductor structure 100 may also include a plurality of input/output (I/O) dies 101 in the upper molding material layer 227. The I/O dies 101 may include a pair of columns of I/O dies 101 on opposing sides of the array 150 in the x-direction. An I/O die 101 in a column of I/O dies 101 may be associated with a row of semiconductor die units 120 in the array 150. The number of I/O dies 101 in each column may be the same as the number of rows of semiconductor die units 120 in the array 150. Thus, as illustrated in FIG. 1A, each column of the I/O dies 101 may include ten (10) I/O dies that extend lengthwise in the y-direction and are substantially aligned with the ten (10) rows of semiconductor die units 120.

The I/O dies 101 may also include a pair of rows of I/O dies 101 on opposing sides of the array 150 in the y-direction. An I/O die 101 in a row of I/O dies 101 may be associated with a column of semiconductor die units 120 in the array 150. The number of I/O dies 101 in each row may be the same as the number of columns of semiconductor die units 120 in the array 150. Thus, as illustrated in FIG. 1A, each row of the I/O dies 101 may include eight (8) I/O dies that extend lengthwise in the x-direction and are substantially aligned with the eight (8) columns of semiconductor die units 120.

The semiconductor structure 100 may also include a plurality of fastening holes 102 in the upper molding material layer 227. The fastening holes 102 may be substantially aligned in the x-direction and the y-direction. The fastening holes 102 may be located at the corners of the semiconductor die units 120, respectively. The fastening holes 102 may be substantially located between the plurality of rows and the plurality of columns of the array 150.

As illustrated in FIG. 1B, each of the plurality of semiconductor die units 120 may include a plurality of semiconductor dies 140 including one or more first dies 141 (e.g., primary dies), one or more second dies 142 (e.g., secondary dies) and one or more third dies 143 (e.g., secondary dies). Additional semiconductor dies 240 (e.g., secondary dies 240 may be located between the semiconductor die units 120 in the y-direction. Each of the semiconductor dies 140 and the semiconductor dies 240 may include, for example, a singular semiconductor die, a system on chip (SoC) die, or a system on integrated chips die, and may be implemented by chip on wafer on substrate technology or integrated fan-out on substrate technology. In particular, each of the semiconductor dies 140 may include, for example, a semiconductor chip or chiplet for a high performance computing (HPC) application, an artificial intelligence (AI) application, and a 5G cellular network application, a logic die (e.g., mobile application processor, microcontroller, etc.), or a memory die (e.g., high-bandwidth memory (HBM) die, hybrid memory cube (HMC), dynamic random access memory (DRAM) die, a Wide I/O die, a M-RAM die, a R-RAM die, an inverted AND (NAND) die, static random access memory (SRAM), etc.), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a high data rate transceiver die, a I/O interface die, an integrated passive device (IPD) die, a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc. Other dies are within the contemplated scope of this disclosure.

In at least one embodiment, the first semiconductor die 141 may include an SoC die, the second semiconductor die 142 may include an HBM die, and the third semiconductor die 143 may include an I/O die. For ease of understanding, the first semiconductor die 141 may be referred to as SoC die 141, the second semiconductor die 142 may be referred to as HBM die 142, and the third semiconductor die 143 may be referred to as I/O die 143.

As illustrated in FIG. 1B, the SoC die 141 may be centrally located in the semiconductor die units 120. A length of the SoC die 141 in the y-direction may be greater than a length of the SoC die 141 in the x-direction. The SoC die 141 may have a pair of short sides facing in the y-direction and pair of long sides facing in the x-direction. In at least one embodiment, a length of the SoC die 141 in the y-direction may be substantially the same as a length of the semiconductor die unit 120 in the y-direction.

The HBM dies 142 may be located on the opposing long sides of the SoC die 141 in a row direction. In particular, the HBM dies 142 may be located at the corners of the semiconductor die units 120. Each of the HBM dies 142 may include a side that is substantially aligned with one of the short sides of the SoC die 141. The fastening holes 102 may be adjacent the HBM dies 142 at the corners of the semiconductor die units 120.

Each of the semiconductor die units 120 may further include a pair of I/O dies 143 on the opposing long sides of the SoC die 141 in the row direction and between the HBM dies 142. The I/O dies 143 may have a length in the x-direction that is substantially the same as a length of the HBM dies 142 in the x-direction. An outer side of the I/O dies 143 facing in the x-direction may be substantially aligned with an outer side of the HBM dies 142 facing in the x-direction.

Each of the semiconductor die units 120 may also include a plurality of interconnect 201. The interconnect dies 201 may be located beneath the SoC die 141 and the HBM dies 142 and are, therefore, shown by shadowing and dashed lines in FIG. 1B. Each of the interconnect dies 201 may serve to interconnect one of the HBM dies 142 with the SoC die 141.

As illustrated in FIG. 1C, the fastening holes 102 may be located between the semiconductor die units 120 in this cross-sectional view. The fastening holes 102 may extend through an entire thickness of the semiconductor structure 100. A spacing of the fastening holes 102 may be substantially uniform in the semiconductor structure 100. A diameter of the fastening holes 102 may be substantially uniform in the z-direction (e.g., a thickness direction). A distance between the fastening holes 102 and the HBM dies 142 of the semiconductor die units 120 may be substantially the same in the semiconductor structure 100.

The semiconductor structure 100 may include a lower RDL structure 120A, a lower molded portion 120B on the lower RDL structure 120A, an upper RDL structure 120C on the lower molded portion 120B, and an upper molded portion 120D on the upper RDL structure 120C. The upper molded portion 120D may include the upper molding material layer 227 that includes the semiconductor dies 140. The fastening holes 102 may extend through each of the lower RDL structure 120A, the lower molded portion 120B, the upper RDL structure 120C and the upper molded portion 120D.

As further illustrated in FIG. 1C, a guard ring 300 may be formed around at least a portion of the fastening holes 102. In at least one embodiment, the guard ring 300 may be located in each of the lower RDL structure 120A, the lower molded portion 120B and the upper RDL structure 120C. In at least one embodiment, the guard ring 300 may be formed of a metal such as copper. Other materials may be used for the guard ring 300. In at least one embodiment, the guard ring 300 may be formed of the same material as the various metal structures (e.g., metal layers, metal vias, etc.) in the lower RDL structure 120A, the lower molded portion 120B and the upper RDL structure 120C.

The guard ring 300 may provide mechanical reinforcement in the semiconductor structure 100. In particular, the guard ring 300 may strengthen the area around the fastening holes 102, distributing mechanical stress that might otherwise cause cracking or deformation in the material around the fastening holes 102. The guard ring 300 may also provide additional support to prevent the surrounding material from breaking or delaminating under repeated thermal cycling or mechanical vibrations.

The guard ring 300 may also act as a barrier between a fastening member in the fastening hole 102 and the various components of the semiconductor structure 100. In particular, the guard ring 300 may serve as a thermal barrier, isolating heat generated by the fastening member during assembly (e.g., friction) or operation in embodiments in which the fastening member is located near a heat source. The guard ring 300 may help maintain the thermal integrity of the material around the fastening hole 102 and around the guard ring 300. The guard ring 300 may also prevent moisture, dust, and other contaminants from seeping into the fastening hole 102, which could lead to corrosion, electrical shorts, or degradation of the material around the fastening hole 102.

In embodiments in which the fastening member is electrically conductive and near sensitive electronic components, the guard ring 300 may also provide an additional barrier to prevent electrical interference or short circuits. This may be useful and impactful in instances in which the fastening member is grounded or carries a potential difference.

Referring again to FIG. 1D, the semiconductor die unit 120 may include the lower RDL structure 120A, the lower molded portion 120B, the upper RDL structure 120C and the upper molded portion 120D. In at least one embodiment, the lower RDL structure 120A may include a plurality of polymer layers 12 and a plurality of redistribution layers 12a stacked alternately. In at least one embodiment, the lower RDL structure 120A may include six (6) redistribution layers 12a. However, the number of redistribution layers 12a and the number of the polymer layers 12 in the lower RDL structure 120A are not limited by the disclosure. A greater or lesser number of redistribution layers and polymer layers may be implemented.

In at least one embodiment, the polymer layers 12 may include, for example, polyimide (PI), epoxy resin, acrylic resin, phenol resin, benzocyclobutene (BCB), polybenzoxazole (PBO), or any other suitable polymer-based dielectric material. The redistribution layers 12a may include one or more conductive materials such as metal materials. The conductive materials may include, for example, one or more layers and may include metals, metal alloys, and/or other metal-containing compounds (e.g., Cu, Al, Mo, Co, Ru, W, TiN, TaN, WN, etc.). In at least one embodiment, the conductive materials may include metal such as copper, aluminum, nickel, titanium, a combination thereof. Other suitable conductive materials may be within the contemplated scope of disclosure.

The redistribution layers 12a may include metallic connection structures, i.e., metallic structures that provide electrical connection between nodes in the structure. The redistribution layers 12a may include a metallic seed layer and a metallic fill material on the metallic seed layer. The metallic seed layer may include, for example, a stack of a titanium barrier layer and a copper seed layer. The titanium barrier layer may have thickness in a range from 50 nm to 500 nm, and the copper seed layer may have a thickness in a range from 50 nm to 500 nm, although lesser or greater thicknesses may also be used. The metallic fill material for the redistribution layers 12a may include copper, nickel, or copper and nickel. Other suitable metallic fill materials are within the contemplated scope of disclosure. The thickness of the metallic fill material that is deposited for each redistribution layers 12a may be in a range from 2 microns to 40 microns, such as from 4 microns to 10 microns, although lesser or greater thicknesses may also be used.

In at least one embodiment, the redistribution layers 12a may include a plurality of metal traces (lines) and a plurality of metal vias connecting the plurality metal traces to each other. The metal traces may be respectively located on the polymer layers 12 and may extend in the x-direction (first horizontal direction) and γ-direction (second horizontal direction) on a surface (e.g., a lower surface) of the polymer layers 12.

The lower RDL structure 120A may also include a plurality of upper bonding pads 125 on an upper surface of the lower RDL structure 120A. The upper bonding pads 125 may be formed of the same material as the redistribution layers 12a. The upper bonding pads 125 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A ball-grid array (BGA) 180 may be formed on a board-side surface (e.g., bottom surface) of the lower RDL structure 120A. The BGA 180 may include, for example, a plurality of C4 bumps 121 on the board-side surface of the semiconductor die unit 120. The C4 bumps 121 may be electrically coupled to the redistribution layers 12a. The C4 bumps 121 may include a metal pillar (e.g., copper pillar) (not shown) and a solder bump (e.g., SnAg solder bump) on the metal pillar. In at least one embodiment, the solder bump may be collapsed to join the metal pillar of the C4 bump 121 to a package substrate, printed circuit board (PCB), etc. The BGA 180 may alternatively or additionally include a plurality of solder balls (not shown).

The lower molded portion 120B may be formed on the lower RDL structure 120A. The lower molded portion 120B may have a length in the x-direction that is substantially the same as a length in the x-direction of the lower RDL structure 120A. The lower molded portion 120B may have a width in the y-direction that is substantially the same as a width in the y-direction of the lower RDL structure 120A. The lower molded portion 120B may have a thickness in the z-direction less than a thickness of the lower RDL structure 120A.

The lower molded portion 120B may include a lower molding material layer 127 (e.g., encapsulation layer) formed on the lower RDL structure 120A. In at least one embodiment, the lower molding material layer 127 may be formed of a curable material that may cure to form a hard, solid structure. The lower molding material layer 127 may include, for example, epoxy molding compound (EMC). In at least one embodiment, the lower molding material layer 127 may include a polymeric material and in particular, an epoxy-based polymeric material. Other suitable molding materials may be used.

In at least one embodiment, the lower molding material layer 127 may have a coefficient of thermal expansion (CTE) that is substantially similar to a CTE of the lower RDL structure 120A. In at least one embodiment, the lower molding material layer 127 may include an added material (e.g., filler material) for improving a property of the lower molding material layer 127 (e.g., thermal conductivity, CTE, etc.). The added material may include, for example, metal powder, metal oxide powder, etc. Other materials in the lower molding material layer 127 are within the contemplated scope of the disclosure.

The lower molded portion 120B of the semiconductor die unit 120 may also include one or more interconnect dies 201. The interconnect dies 201 may be mounted on the lower RDL structure 120A so that a frontside of the interconnect dies 201 faces away from the lower RDL structure 120A. The interconnect dies 201 may alternatively or additionally be mounted on the lower RDL structure 120A such that a backside of the interconnect dies 201 faces away from the lower RDL structure 120A. In particular, the interconnect dies 201 may be mounted on the upper bonding pads 125 of the lower RDL structure 120A. Each of the interconnect dies 201 may have a similar structure and function or, alternatively, a different structure and function. The interconnect dies 201 may have a thickness in a range from 10 μm to 70 μm (e.g., about 40 μm).

The interconnect dies 201 may be surrounded (e.g., at least in the x-direction and y-direction) by the lower molding material layer 127. In at least one embodiment, the lower molding material layer 127 may contact a substantial entirety of the sidewalls of the interconnect dies 201 (e.g., the interconnect dies 201 may be substantially embedded in the lower molding material layer 127. The interconnect dies 201 may interconnect (e.g., electrically couple) the SoC die 141 to the HBM dies 142 (see FIG. 1B). Each of the interconnect dies 201 may include at least a portion located under the SoC die 141 and at least a portion located under an HBM die 142. The interconnect dies 201 may also electrically couple the upper RDL structure 120C to the RDL layers 12a in the lower RDL structure 120A. In at least one embodiment, at least 25% of an interconnect die 201 may be located under the SoC die 141 and at least 25% of the interconnect die 201 may be located under an HBM die 142. In at least one embodiment, a center point of the interconnect die 201 in the x-direction may be substantially aligned with a center point of a gap between the SoC die 141 and an HBM die 142.

The interconnect dies 201 may be attached (e.g., electrically coupled) to the lower RDL structure 120A by a plurality of microbumps 28. The microbumps may be formed in a first polymer layer 21 of the interconnect dies 201. The microbumps 28 may include, for example, solder caps on metal pillars (e.g., copper pillars). The interconnect dies 201 may attached to the lower RDL structure 120A by a direct bond (e.g., dual bond) including the microbumps 28 and the first polymer layer 21. The direct bond may include, for example, a dielectric-dielectric bond between the first polymer layer 21 and a second polymer layer 22 around the upper bonding pads 125. The direct bond may also include a metal-metal bond between the microbumps 28 (e.g., the solder caps of the microbumps 28) and the upper bonding pads 125.

The interconnect dies 201 may alternatively or additionally be attached to the lower RDL structure 120A without the use of a direct bond. In that case, an interconnect die underfill layer (not shown) may be formed under and around the interconnect dies 201. The interconnect die underfill layer may also be formed around the microbumps 28. The interconnect die underfill layer may thereby fix each of the interconnect dies 201 to the upper surface of the lower RDL structure 120A. The interconnect die underfill layer may be formed of an epoxy-based polymeric material. Other suitable materials may be used for the interconnect die underfill layer.

The interconnect dies 201 may also include a bulk semiconductor region 23 including one or more through silicon vias (TSVs) 24. The bulk semiconductor region 23 may include a semiconductor material such as silicon, germanium, etc. The TSVs 24 may be electrically coupled to the microbumps 28 by a backside RDL structure 25 including one or more redistribution layers. The backside RDL structure 25 may have a structure substantially similar to a structure of the lower RDL structure 120A.

The interconnect dies 201 may also include an active region (not shown) that may include one or more active devices such as transistors, diodes, thyristors, etc. The active region may be adjacent the bulk semiconductor region and electrically coupled to the TSVs 24.

The interconnect dies 201 may also include a passivation layer 26 including a plurality of metal pads 26a (e.g., aluminum pads). The metal pads 26a may be electrically coupled to the plurality of TSVs 24. The interconnect dies 201 may also include a third polymer layer 27 including a plurality of frontside metal vias 27a (e.g., frontside copper vias). The frontside metal vias 27a may be electrically coupled to the TSVs 24 by the metal pads 26a in the passivation layer 26.

The RDL structure 25, the TSVs 24, the metal pads 26a and the frontside metal vias 27a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The lower molded portion 120B may also include one or more through insulation vias (TIVs) 202 in the lower molding material layer 127. The TIVs 202 may be formed on the upper bonding pads 125 of the lower RDL structure 120A. The TIVs 202 may electrically couple the upper RDL structure 120C to the redistribution layers 12a of the lower RDL structure 120A. The TIVs 202 may alternatively or additionally be electrically isolated from the lower RDL structure 120A and/or the upper RDL structure 120C. The TIVs 202 may also help to dissipate heat from the interconnect dies 201 in the lower molding material layer 127. The TIVs 202 may, therefore, help to reduce the risk of increasing the temperature of the semiconductor dies 140 (in particular, the HBM dies 142) from high power density areas in the interconnect dies 201.

The TIVs 202 may extend lengthwise in the z-direction across an entire thickness of the lower molding material layer 127. The TIVs 202 may extend from an upper surface of the lower RDL structure 120A to a lower surface of the upper RDL structure 120C. The TIVs 202 may have a width (e.g., diameter) in the first direction (x-direction) in a range from 1% to 10% of a width of the interconnect dies 201. The TIVs 202 may be formed of substantially the same material as the TSVs 24 in the interconnect dies 201. The TIVs 202 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The lower molded portion 120B may also integrate additional elements, such as one or more stand-alone IPDs (not shown). In at least one embodiment, the IPDs may be located in the lower molding material layer 127 underneath one or more of the semiconductor dies 140 to support signal communication.

Referring again to FIG. 1D, the upper RDL structure 120C of the semiconductor die unit 120 may have a structure substantially similar to that of the lower RDL structure 120A. In particular, the upper RDL structure 120C may include a plurality of polymer layers 13 and a plurality of redistribution layers 13a stacked alternately. In at least one embodiment, the upper RDL structure 120C may include redistribution layers 12a. However, the number of redistribution layers 13a and the number of the polymer layers 13 in the upper RDL structure 120C are not limited by the disclosure. The materials that may be used in the polymer layers 13 may be substantially the same as the materials that may be used in the polymer layers 12. The materials that may be used in the redistribution layers 13a may bs substantially the same as the materials that may be used in the redistribution layers 12a. The structure (e.g., thickness) of the redistribution layers 13a may be substantially the same as the structure of the redistribution layers 12a.

The redistribution layers 13a (e.g., metal vias) in the upper RDL structure 120C may contact the frontside metal vias 27a of the interconnect dies 201 in the lower molded portion 120B. The redistribution layers 13a (e.g., metal vias) in the upper RDL structure 120C may also contact the TIVs 202 in the lower molded portion 120B. The redistribution layers 13a may, therefore, be electrically coupled to the redistribution layers 12a in the lower RDL structure 120A through the interconnect dies 201 and through the TIVs 202.

The upper RDL structure 120C may also include a plurality of bonding pads 214 on an upper surface of the upper RDL structure 120C. The bonding pads 214 may be substantially similar to the upper bonding pads 125 of the lower RDL structure 120A. In particular, the materials that may be used in the bonding pads 214 may be substantially the same as the materials that may be used in the upper bonding pads 125.

As illustrated in FIG. 1D, the upper molded portion 120D of the semiconductor die unit 120 may be formed on the upper RDL structure 120C. The upper molded portion 120D may include the semiconductor dies 140. The semiconductor dies 140 may include die bonding pads 145. The semiconductor dies 140 may be electrically coupled to the bonding pads 214 through the die bonding pads 145.

In at least one embodiment, a manner of attaching the SoC die 141 to the upper RDL structure 120C may be different than a manner of attaching the HBM dies 142 to the upper RDL structure 120C. The SoC die 141 may be attached to the upper RDL structure 120C by a direct bond substantially similar to the direct bond between the interconnect dies 201 and the lower RDL structure 120A described above.

In particular, the SoC die 141 may be attached (e.g., electrically coupled) to the upper RDL structure 120C by a plurality of microbumps 228 formed in a die polymer layer 221 of the SoC die 141. The microbumps 228 may include, for example, solder caps on metal pillars (e.g., copper pillars). The SoC die 141 may be attached to the upper RDL structure 120C by a direct bond (e.g., dual bond) including the microbumps 228 and the die polymer layer 221. The direct bond may include, for example, a dielectric-dielectric bond between the die polymer layer 221 and a polymer layer 222 around the bonding pads 214. The direct bond may also include a metal-metal bond between the microbumps 228 (e.g., the solder caps of the microbumps 228) and the bonding pads 214.

The HBM dies 142 and the I/O dies 143 (see FIG. 1B) may be attached to the upper RDL structure 120C by microbumps 128. In at least one embodiment, the microbumps 128 may have a size and pitch greater than a size and pitch of the microbumps 228 that attach the SoC die 141 to the upper RDL structure 120C. A semiconductor die underfill layer 129 may be formed (e.g., individually or collectively) under and around each of the HBM dies 142 and the I/O dies 143. The semiconductor die underfill layer 129 may also be formed around the microbumps 128. The semiconductor die underfill layer 129 may thereby fix the HBM dies 142 and the I/O dies 143 to the upper RDL structure 120C. The semiconductor die underfill layer 129 may be formed of an epoxy-based polymeric material. Other suitable materials may be used for the semiconductor die underfill layer 129.

The semiconductor die unit 120 may also include the upper molding material layer 227 formed around the semiconductor dies 140. The upper molding material layer 227 may also be formed on and around the semiconductor die underfill layer 129. The upper molding material layer 227 may have an outer sidewall that is substantially aligned with an outer sidewall of the polymer layers 13 in the upper RDL structure 120C, an outer sidewall of the lower molding material layer 127 and an outer sidewall of the polymer layers 12 in the lower RDL structure 120A.

In at least one embodiment, the upper molding material layer 227 may be formed on sidewalls (inner sidewall and outer sidewall) of each of the semiconductor dies 140. In at least one embodiment, an upper surface of the semiconductor die underfill layer 129 may be recessed from upper surface 140a of the semiconductor dies 140. In that case, the upper molding material layer 227 may be formed on the upper surface of the semiconductor die underfill layer 129 between the semiconductor dies 140. The upper molding material layer 227 may be formed between and bonded to the sidewalls of each of the semiconductor dies 140. The upper molding material layer 227 may also be bonded to the chip-side surface of the upper RDL structure 120C and the semiconductor die underfill layer 129.

As illustrated in FIG. 1D, the upper molding material layer 227 may include an upper surface that is substantially coplanar with the upper surface 140a of the semiconductor dies 140. The upper surface of the upper molding material layer 227 may alternatively or additionally include a recessed upper surface (not shown) that is recessed in the z-direction from the upper surface 140a of the semiconductor dies 140. In at least one embodiment, the recessed upper surface may constitute an entirety of an upper surface of the upper molding material layer 227.

In at least one embodiment, the upper molding material layer 227 may be formed of a curable material that may cure to form a hard, solid structure. The upper molding material layer 227 may include, for example, epoxy molding compound (EMC). In at least one embodiment, the upper molding material layer 227 may include a material that is substantially similar to the semiconductor die underfill layer 129, and or substantially similar to the lower molding material layer 127 in the lower molded portion 120B. In at least one embodiment, the upper molding material layer 227 may include a polymeric material and in particular, an epoxy-based polymeric material. Other suitable molding materials may be within the contemplated scope of disclosure.

In at least one embodiment, the upper molding material layer 227 may have a CTE that is substantially similar to a CTE of the upper RDL structure 120C, a CTE of the lower molded portion 120B and/or a CTE of the lower RDL structure 120A. In at least one embodiment, the upper molding material layer 227 may include an added material (e.g., filler material) for improving a property of the upper molding material layer 227 (e.g., thermal conductivity, CTE, etc.). The added material may include, for example, metal powder, metal oxide powder, etc. Other materials in the upper molding material layer 227 are within the contemplated scope of the disclosure.

As further illustrated in FIG. 1D, the semiconductor die unit 120 may include the guard ring 300 adjacent the fastening holes 102. The guard ring 300 may include a lower RDL portion 302 in the lower RDL structure 120A. The lower RDL portion 302 may include, for example, metal layers and metal vias having a structure substantially the same as the redistribution layers 12a in the lower RDL structure 120A. The lower RDL portion 302 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The guard ring 300 may also include a lower via portion 304 in the lower molded portion 120B. The lower via portion 304 have a structure substantially similar to a structure of the TIVs 202. In particular, the lower via portion 304 may include one or more of metal vias (TIVs) formed on the upper bonding pads 125 of the lower RDL structure 120A. In at least one embodiment the lower via portion 304 may include the upper bonding pad 125. The upper bonding pad 125 may alternatively be omitted so that the lower via portion 304 includes only the metal via without the upper bonding pad 125. The lower via portion 304 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The guard ring 300 may include an upper RDL portion 306 in the upper RDL structure 120C. The upper RDL portion 306 may be electrically coupled to the lower RDL portion 302 through the lower via portion 304. The upper RDL portion 306 may include, for example, metal layers and metal vias having a structure substantially the same as the redistribution layers 13a in the upper RDL structure 120C. The upper RDL portion 306 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

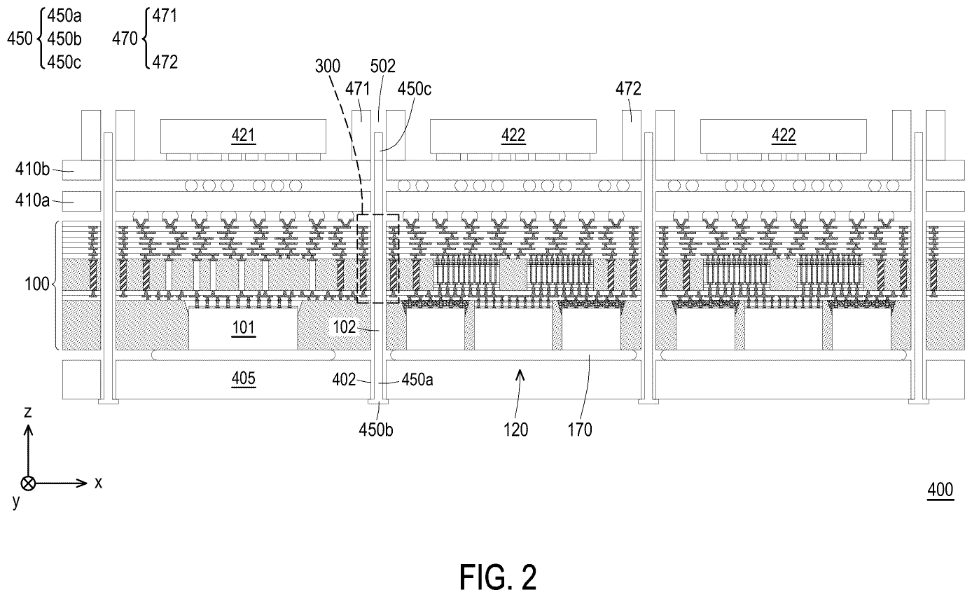

FIG. 2 is a cross-sectional view of an SoP structure 400 according to one or more embodiments. As illustrated in FIG. 2, the SoP structure 400 may include the semiconductor structure 100 including the semiconductor die units 120. In particular, a thermal interface material (TIM) layer 170 may be formed on the semiconductor die units 120 and the I/O dies 101 of the semiconductor structure 100 as shown in FIG. 1C. The TIM layer 170 may be formed on the semiconductor die units 120 and I/O dies 101 to dissipate of heat generated during operation of the semiconductor structure 100.

The TIM layer 170 may include one or more layers. The TIM layer 170 may cover an entire area of the upper surface of the semiconductor die unit 120 or an entire area of the upper surface of the I/O die 101. In at least one embodiment, the TIM layer 170 may have a thickness (e.g., a greatest thickness in the z-direction) in a range from 100 μm to 300 μm. The TIM layer 170 may be attached to the upper surface of the semiconductor die unit 120 or the upper surface of the I/O die 101 by a thermally conductive adhesive (not shown).

The TIM layer 170 may have a low bulk thermal impedance and high thermal conductivity. In at least one embodiment, the TIM layer 170 may include one or more metals. The TIM layer 170 may include, for example, a low-melting-temperature (LMT) metal TIM or liquid metal TIM. The TIM layer 170 may include one or more metals such as indium, tin, gallium, silver, etc. The TIM layer 170 may include, for example, a gallium base, indium base, silver base, solder base, etc. The solder base may include tin and one or more other elements such as copper, silver, bismuth, indium, zinc, antimony, etc.

The TIM layer 170 may alternatively or additionally include a thermal grease, a thermal paste, thermal film, thermal adhesive, thermal gap filler, thermal pad (e.g., silicone), thermal tape or a gel-type TIM (e.g., a cross-linked polymer film). In at least one embodiment, the TIM layer 170 may include graphite, carbon nanotubes (CNTs), phase-change material (PCM), etc. The PCM may include, for example, a polymer based PCM. In at least one embodiment, the PCM may change its phase from solid to high-viscosity semi liquid around 60° C. Other materials in the TIM layer 170 are within the contemplated scope of this disclosure.

A thermal plate 405 may be attached to the semiconductor structure 100 through the TIM layers 170. The thermal plate 405 may help to dissipate heat from the semiconductor structure 100 through the TIM layers 170. The bond-line-thickness (BLT) (e.g., a distance between the thermal plate 405 and the semiconductor die units 120 and I/O units 101) may be less than about 100 μm, although greater or lesser distances may be used. The BLT may also be substantially uniform over the entire area of the semiconductor structure 100. The thermal plate 405 may include a thermally conductive material such as a metal plate. The thermal plate 405 include a plurality of fastening holes 402 that may be substantially aligned with the fastening holes 102 in the semiconductor structure 100.

The semiconductor structure 100 with the cold plate 405 may be mounted on a first PCB 410a. The semiconductor structure 100 may be electrically coupled to the first PCB 410a by the BGA 180. The first PCB 410a may include a plurality of fastening holes 412 that are substantially aligned with the fastening holes 102 in the semiconductor structure 100.

The SoP structure 400 may also include on or more electronic modules mounted on a second PCB 410b. The electronic modules may include, for example, one or more connector modules 421 and one or more voltage regulator (VR) modules 422. The second PCB 410b may be attached to the first PCB 410a opposite the semiconductor structure 100. In particular, the second PCB 410b may be attached to the first PCB 410a such that a connector module 421 is located opposite an I/O die 101 and such that a VR module die 422 is located opposite a semiconductor die unit 120. The second PCB 410b may also include a plurality of fastening holes 412 that are substantially aligned with the fastening holes 102 in the semiconductor structure 100.

The thermal plate 405, semiconductor structure 100, first PCB 410a and second PCB 410b may be fastened together by a fastening member 450. The fastening member 450 may include, for example, a screw, bolt, etc. The fastening member 450 may be formed, for example, of a metal material or other suitable material.

In at least one embodiment, a liner layer (not shown) may be formed on the wall of the fastening hole 102 in the semiconductor structure 100. The liner layer may provide additional structural support to the material around the fastening hole 102. The liner layer may include, for example, a polymer material or other suitable materials.

The fastening member 450 may include a rod portion 450a, a head portion 450b at an end of the rod portion 450a, and a threaded portion 450c at an end of the rod portion 450a opposite the head portion 450b. The rod portion 450a, a head portion 450b and threaded portion 450c may be integrally formed as a unit. The rod portion 450a may be inserted in the fastening hole 402 in the thermal plate 405, the fastening hole 102 in the semiconductor structure 100 and the fastening holes 412 in the first PCB 410a and the second PCB 410b.

The head portion 450b may located at the fastening hole 402 in the thermal plate 405. The head portion 450b may contact a surface of the thermal plate 450. A annular-shaped washer (e.g., metal washer) having a size equal to or greater than the head portion 450b, may optionally be located between the head portion 450b and the surface of the thermal plate 450.

The heat portion 450b may be configured to be receive a pressing force for pressing the fastening member 450 into the fastening hole 402 in the thermal plate 405, the fastening hole 102 in the semiconductor structure 100 and the fastening holes 412 in the first PCB 410a and the second PCB 410b. The head portion 450b may also be configured to receive a rotating force on the fastening member 450. The head portion 450b may include, for example, a bold head including a substantially square shape, hexagonal shape, etc. The head portion 450b may additionally or alternatively include a screw head having a substantially circular shape. In some embodiments, a surface of the head portion 450b may include a recesses for receiving a screwdriver head (e.g., straight head, Phillips head, etc.).

The SoP structure 400 may also receive a frame structure including a plurality of ribs 470. The ribs 470 may include, for example, a first rib 471 located between the connector module 421 and a VR module 422. The ribs 470 may also include a second rib 472 located between the VR modules 422. A size of the second ribs 472 may be less than a size of the first ribs 471.

The ribs 470 may have a width in the x-direction in a range from 5 mm to 15 mm (e.g., about 8.35 mm) and a height in the z-direction in a range from 5 mm to 25 mm. The ribs 470 may have a threaded fastening hole 502 with internal threads configured to interface with the external threads of the threaded portion 450c of the fastening member 450. The threaded fastening hole 502 of the ribs 470 may have a diameter, for example, in a range from 1 mm to 8 mm (e.g., about 4 mm to 5 mm). The threaded portion 450c of the fastening member 450 may be screwed into the ribs 470 to securely fasten together the thermal plate 405, semiconductor structure 100, first PCB 410a and second PCB 410b.

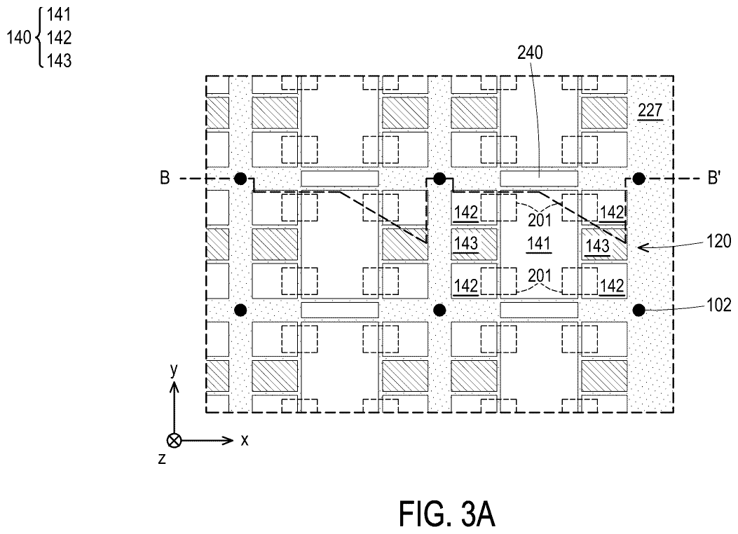

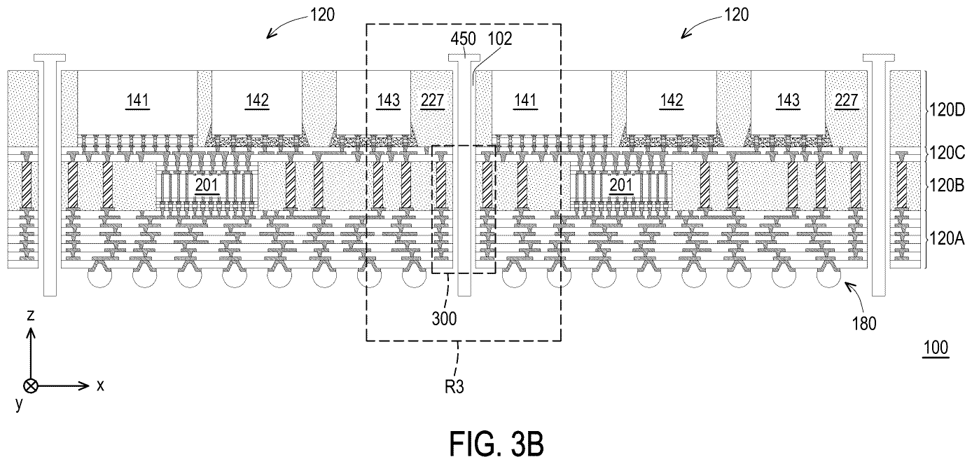

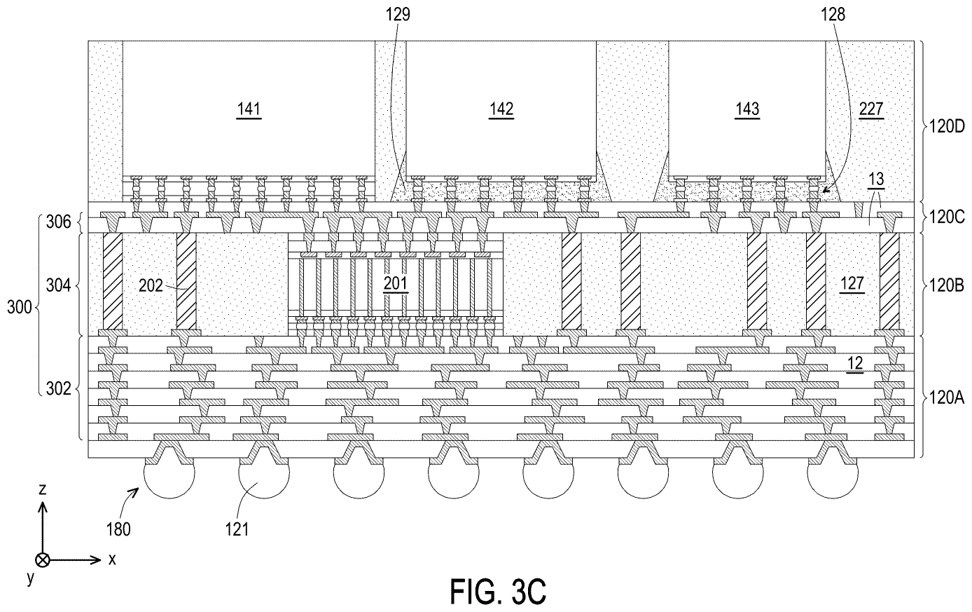

FIGS. 3A-3C illustrate additional views of the semiconductor structure 100 according to one or more embodiments. FIG. 3A is a top-down view of Region R2 of the semiconductor structure 100 in FIG. 1A according to one or more embodiments. FIG. 3B is a vertical cross-sectional view of the portion of the semiconductor structure 100 according to one or more embodiments. The vertical cross-sectional view in FIG. 3B is along the line B-B′ in FIG. 3A. The fastening members 450 are shown in the fastening holes 102 in FIG. 3B for ease of understanding. FIG. 3C is a vertical cross-sectional view of a semiconductor die unit 120 in the semiconductor structure 100 according to one or more embodiments.

As illustrated in FIGS. 3A-3C, along the line B-B′, the SoC die 141 may be adjacent a fastening hole 102. The HBM die 142 may be adjacent the SoC die 141 and the I/O die 143 may be adjacent the HBM die 142. Another fastening hole 102 may be located on a side of the I/O die 143 opposite the HBM die 142. In particular, as illustrated in FIG. 3B, the fastening hole 102 may be located between an I/O die 143 of a semiconductor die unit 120 and an SoC die 141 of another semiconductor die unit 120. The guard ring 300 may, therefore, be located in the lower RDL structure 120A, the lower molded portion 120B and the upper RDL structure 120C between the I/O die 143 and the SoC die 141.

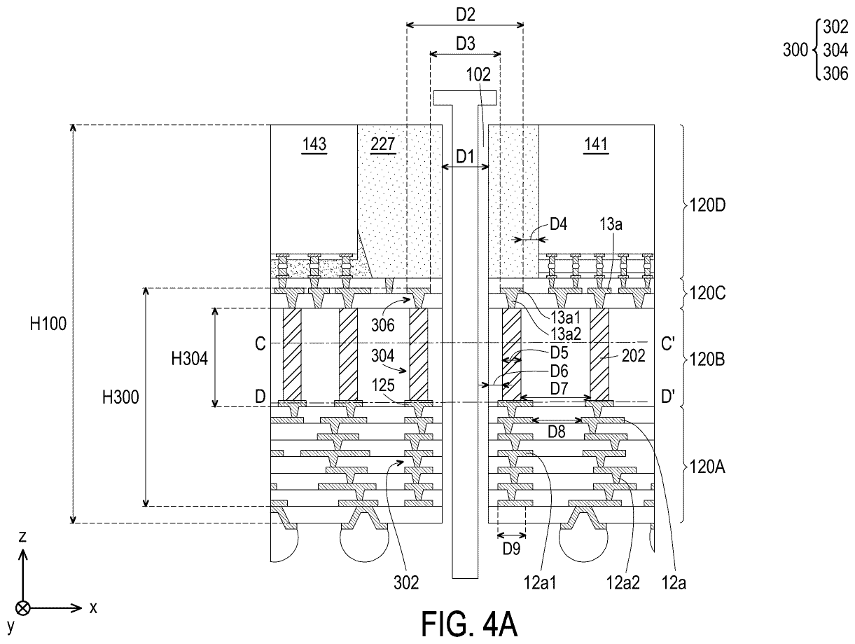

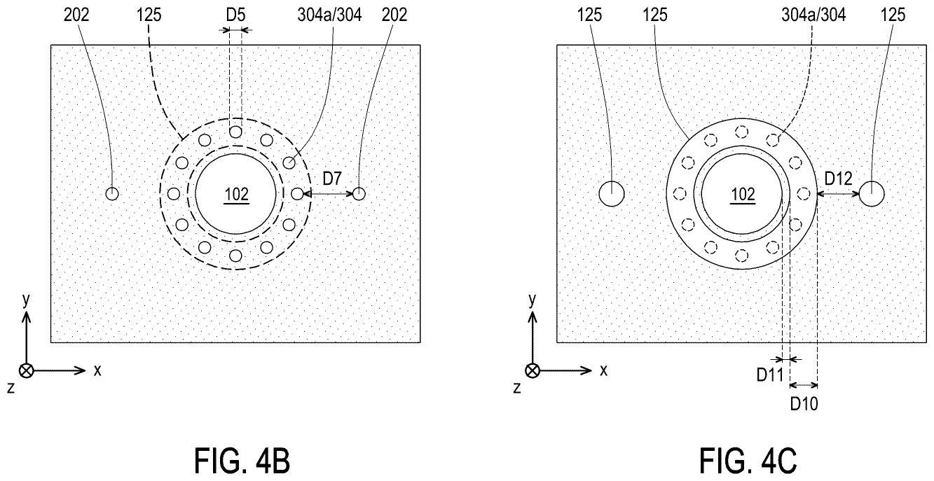

FIGS. 4A-4C are detailed views of the guard ring 300 according to one or more embodiments. FIG. 4A is a vertical cross-sectional view of the region R3 in FIG. 3B according to one or more embodiments. FIG. 4B is a top-down view of the guard ring 300 along line C-C′ in FIG. 4A according to one or more embodiments. FIG. 4C is a top-down view of the guard ring 300 along line D-D′ in FIG. 4A according to one or more embodiments.

As illustrated in FIG. 4A, the fastening holes 102 in the semiconductor structure may have a diameter D1 in a range from 1 mm to 8 mm (e.g., about 4 mm to 5 mm). A size of the fastening holes 102 is not necessarily limited by this disclosure. The guard ring 300 may have an outer width D2 that is at least twice the diameter D1 of the fastening hole 102. In at least one embodiment, the width D2 of the guard ring 300 may be in a range from 2 mm to 16 mm. The guard ring 300 may have an inner width D3 that is at least 30% greater than the diameter D1 of the fastening hole 102. The outer width D2 of the guard ring 300 may be substantially uniform over the entire guard ring 300 and the inner width D3 of the guard ring 300 may be substantially uniform over the entire guard ring 300. Thus, for example, the outer width D2 of the guard ring 300 in the lower RDL structure 120A may be substantially the same as the outer width D2 of the guard ring 300 in the lower molded portion 120B. The guard ring 300 may be separated from the semiconductor dies 140 in the upper molded portion 120D by a distance D4 greater than 1.0 mm.

The lower via portion 304 of the guard ring 300 may have a width D5 in a range from 50 μm to 300 μm (e.g., about 120 μm to 200 μm). The lower via portion 304 may be separated from the fastening hole 102 by a distance D6 in a range from 50 μm to 200 μm (e.g., about 100 μm to 150 μm). The lower via portion 304 may also be separated from an adjacent TIV 202 in the lower molding material layer 127 by a distance D7 greater than 2 mm.

The lower RDL portion 302 of the guard ring 300 may include metal traces 12a1 and metal vias 12a2 of the redistribution layers 12a in the lower RDL structure 120A. Each of the metal traces 12al and the metal vias 12a2 may have an annular shape around the fastening hole 102 in the top-down view. The metal traces 12al may be substantially aligned in the z-direction. The metal traces 12al may be separated from an adjacent redistribution layer 12a by a distance D8 greater than 1 mm. The metal traces 12a1 may be substantially aligned with the upper bonding pad 125 of the lower via portion 304. The metal traces 12al may also have a width D9 greater than or equal to a width of the upper bonding pad 125 of the lower via portion 304. The width D9 of the metal traces 12al may also be greater than or equal to the width D5 of the lower via portion 304.

The upper RDL portion 306 of the guard ring 300 may include metal traces 13al and metal vias 13a2 of the redistribution layers 13a in the upper RDL structure 120C. Each of the metal traces 13al and the metal vias 13a2 may have an annular shape around the fastening hole 102 in the top-down view. The metal traces 13al may be substantially aligned in the z-direction. The metal traces 13al may be separated from an adjacent redistribution layer 13a by the distance D8 greater than 1 mm. The metal traces 13al may also have the width D9 greater than or equal to the width D5 of the lower via portion 304.

The semiconductor structure 100 may have a height H100 in a range from 150 μm to 5000 μm. The guard ring 300 may have a height H300 that is at least 30% of the height H100 of the semiconductor structure 100. The lower via portion 304 (including a thickness of the upper bonding pad 125 of the lower via portion 304) may have a height H304 that is at least 30% of the height H300 of the guard ring 300. In at least one embodiment, the lower via portion 304 may have a height H304 in a range from 40 μm to 120 μm (e.g., about 70 μm to 90 μm).

As illustrated in FIG. 4B, the upper bonding pad 125 of the lower via portion 304 may have an annular shape and be concentrically formed with the fastening hole 102. The lower via portion 304 may include a plurality of metal vias 304a arranged in a ring on the upper bonding pad 125. Each of the metal vias 304a may have substantially the same width. In particular, each of the metal vias 304a may have the width D5. In at least one embodiment, the ring may include at least 12 metal vias 304a. The ring of metal vias 304a may be concentrically formed with the fastening hole 102. The ring of metal vias 304a may be concentrically formed with the upper bonding pad 125 of the lower via portion 304. The ring of metal vias 304a may also be substantially centered on the upper bonding pad 125.

In FIG. 4C, a location of the ring of metal vias 304a in the lower via portion 304 is indicated by dashed lines. As illustrated in FIG. 4C, the upper bonding pad 125 of the lower via portion 304 may have a width D10 greater than or equal to the width D5 of the lower via portion 304 (e.g., the metal vias 304a of the lower via portion 304). In at least one embodiment, the width D10 of the upper bonding pad 125 of the lower via portion 304 may be at least 50% greater than the width D5 of the lower via portion 304. The upper bonding pad 125 of the lower via portion 304 may also be separated from the fastening hole 102 by a distance D11 in a range from 50 μm to 200 μm (e.g., about 100 μm to 150 μm). The upper bonding pad 125 of the lower via portion 304 may also be separated from an adjacent upper bonding pad 125 by a distance D12 greater than 2 mm.

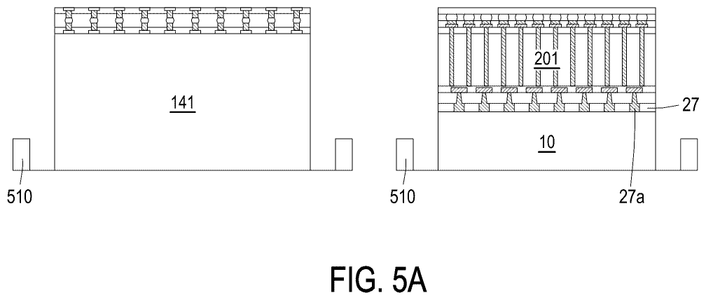

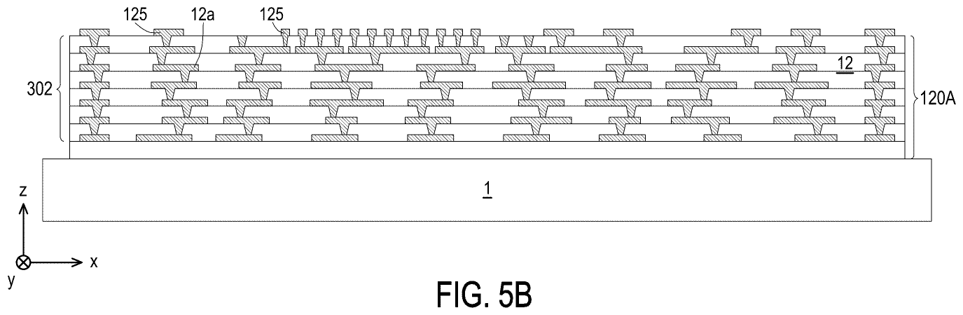

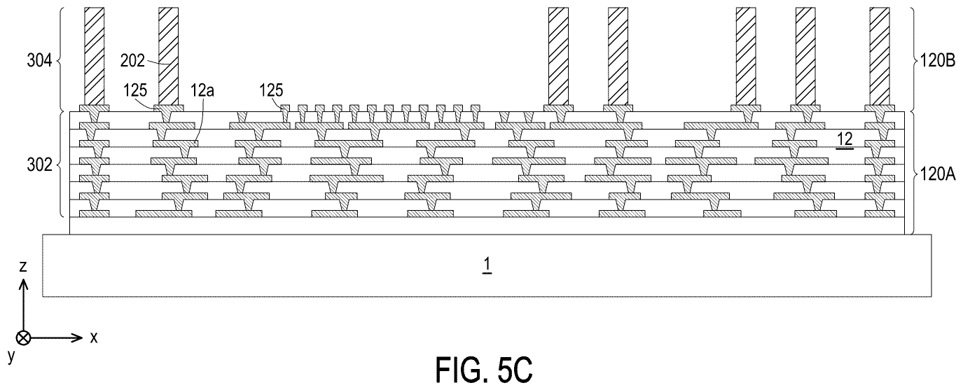

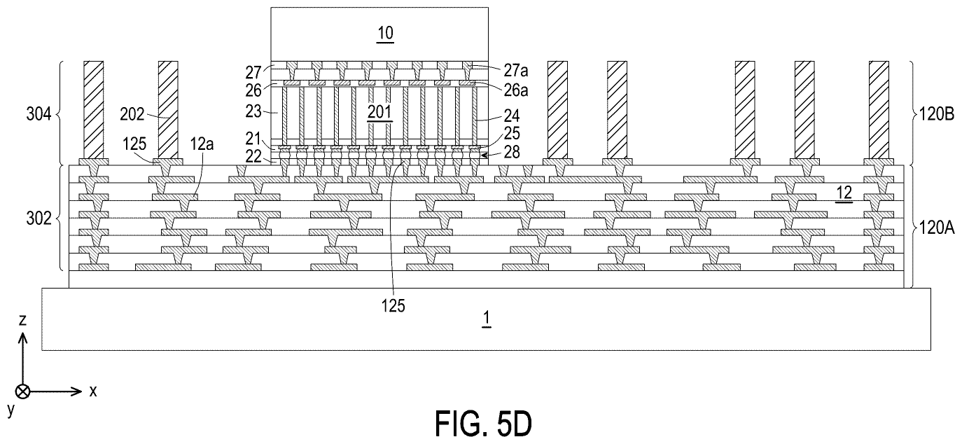

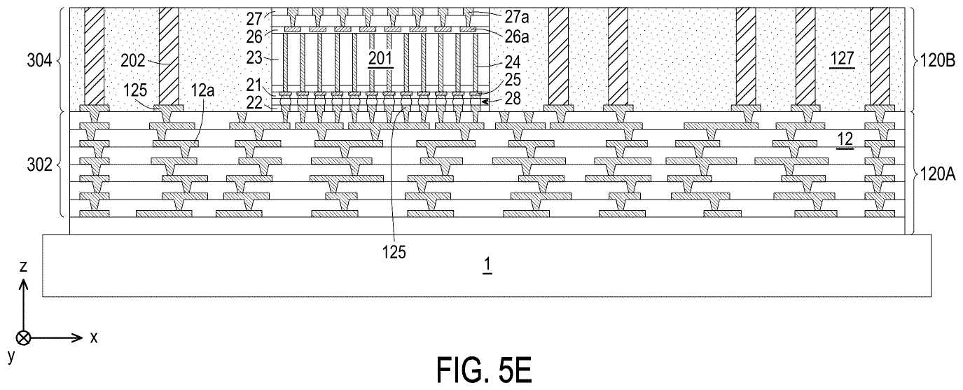

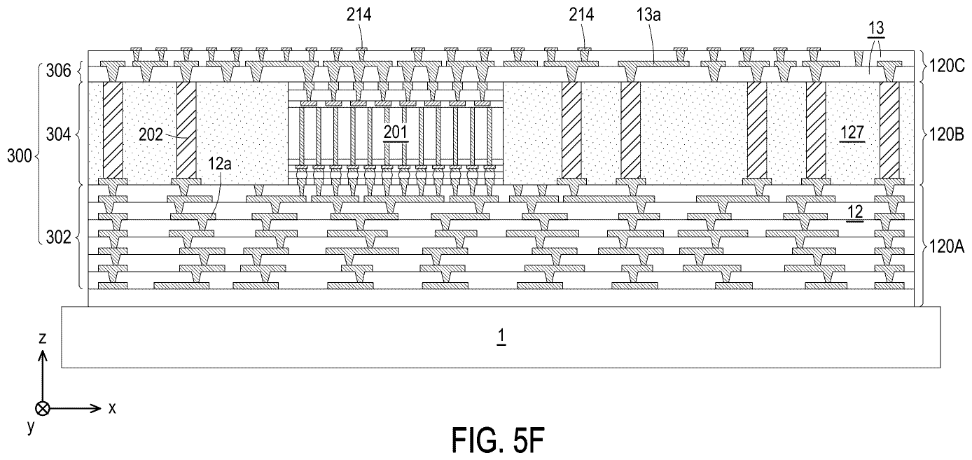

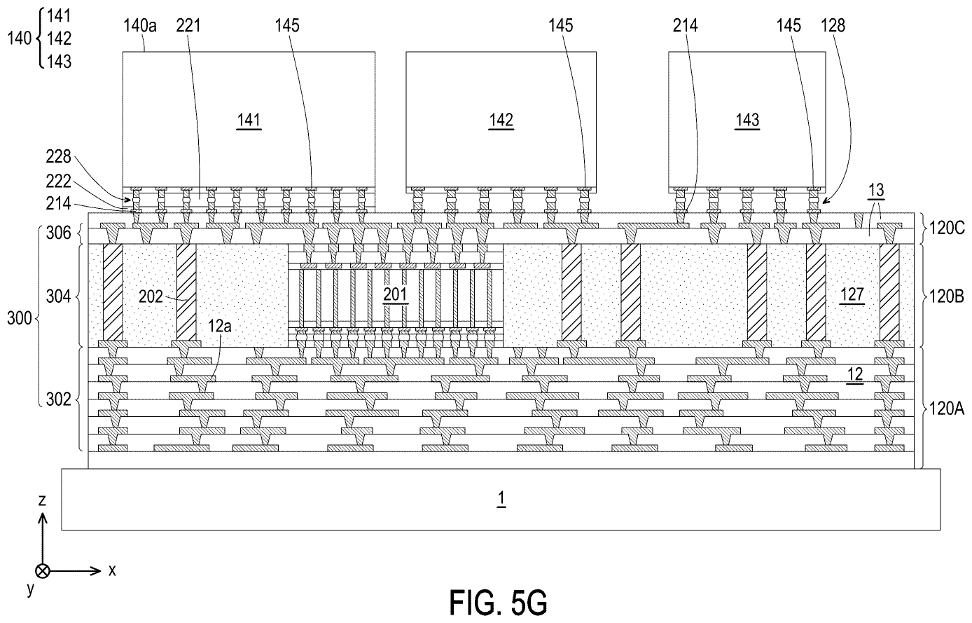

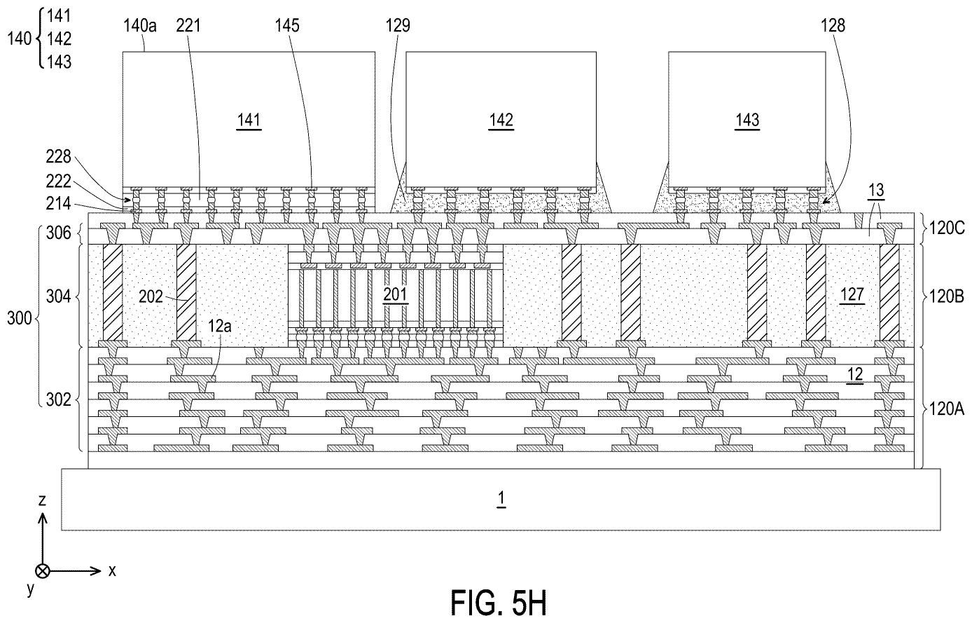

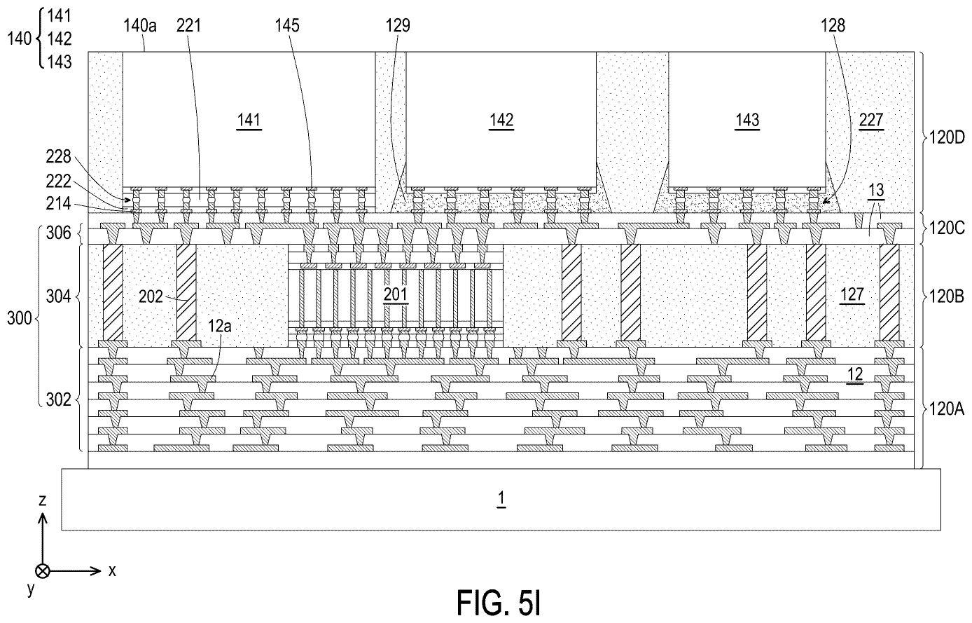

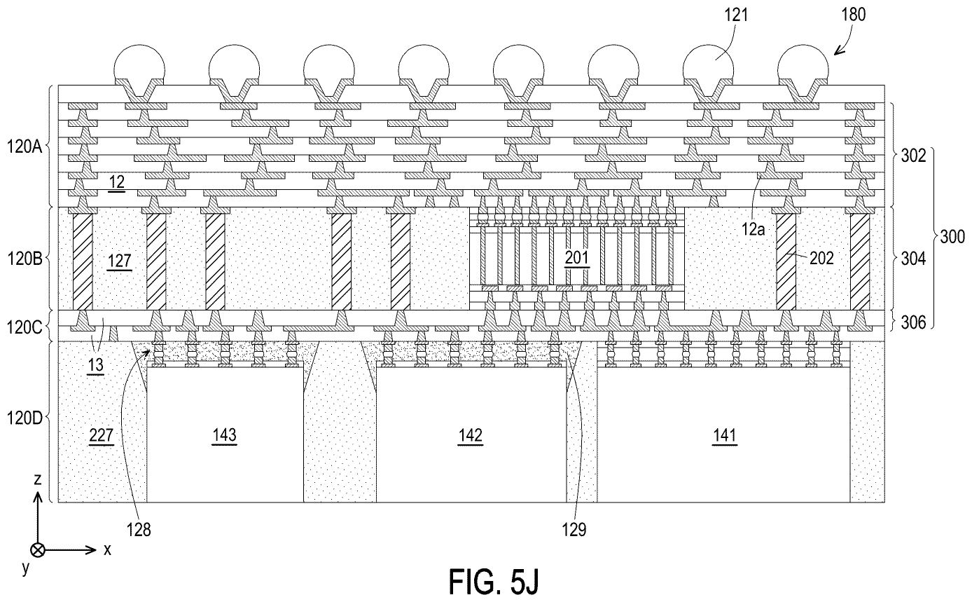

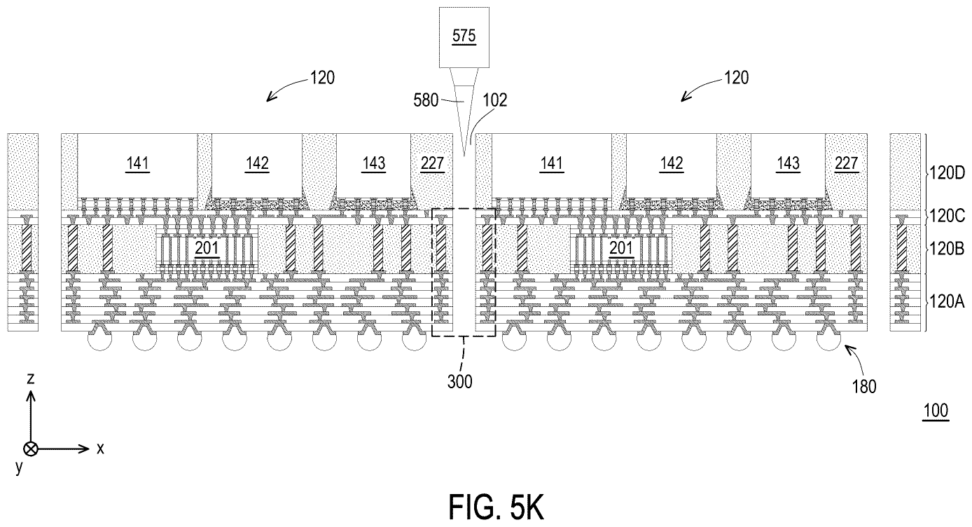

FIGS. 5A-5K illustrate various intermediate structures in a method of forming the semiconductor structure 100 according to one or more embodiments. For ease of understanding, the method steps are illustrated in FIGS. 5A-5J using only one semiconductor die unit 140 of the semiconductor structure. It should be understood that the same processes illustrated in FIGS. 5A-5J may be used to form (e.g., concurrently form) an entirety of the semiconductor structure 100 including all of the semiconductor die units 120 in the semiconductor structure 100.

FIG. 5A is a vertical cross-sectional view of each of the SoC die 141 and the interconnect die 201 on a frame mount 510 according to one or more embodiments. The semiconductor dies 140 and the interconnect dies 201 may be prepared at some point prior to mounting in the semiconductor structure 100. As illustrated in FIG. 5A, the SoC die 141 may be prepared and placed on a frame mount 510 so that a frontside of the SoC die 141 faces away from the frame mount 510. The frame mount 510 may provide physical support to the intermediate structure and ensure that the intermediate structure is securely held in place during the fabrication process.

The interconnect die 201 may be prepared and attached to a carrier 10 (e.g., silicon carrier, dummy silicon) so that a frontside of the interconnect die 201 faces the carrier 10. The carrier 10 may have a thickness in a range from 500 μm to 1000 μm (e.g., about 780 μm). The third polymer layer 27 including a plurality of frontside metal vias 27a may be attached to the carrier 10 through an adhesive layer (not shown). The interconnect die 201 may then be placed on a frame mount 510 so that the carrier 10 contacts the frame mount 510.

FIG. 5B is a vertical cross-sectional view of an intermediate structure including the lower RDL structure 120A on a first carrier substrate 1 according to one or more embodiments. The first carrier substrate 1 may include a circular wafer or a rectangular wafer. The lateral dimensions (such as the diameter of a circular wafer or a side of a rectangular wafer) of the first carrier substrate 1 may be in a range from 100 mm to 500 mm, such as from 200 mm to 400 mm, although lesser and greater lateral dimensions may also be used. The first carrier substrate 1 may include a semiconductor substrate, an insulating substrate, or a conductive substrate. The first carrier substrate 1 may be transparent or opaque. A thickness of the first carrier substrate 1 may be sufficient to provide mechanical support to an array of interposers to be formed thereupon. For example, the thickness of the first carrier substrate 1 may be in a range from 60 microns to 1 mm, although lesser and greater thicknesses may also be used. In at least one embodiment, the carrier substrate 1 may include sapphire or glass and have a thickness of about 1000 μm.

An adhesive layer (e.g., die attach film (DAF); not shown) may be applied to the top surface of the first carrier substrate 1. The adhesive layer may include a light-to-heat conversion (LTHC) layer. The LTHC layer is a solvent-based coating applied using a spin coating method. The LTHC layer may form a layer that converts ultraviolet light to heat such that the LTHC layer loses adhesion. Alternatively, the adhesive layer may include a thermally decomposing adhesive material. For example, the adhesive layer may include an acrylic pressure-sensitive adhesive that decomposes at an elevated temperature. The debonding temperature of the thermally decomposing adhesive material may be in a range from 150° C. to 400° C. Other suitable thermally decomposing adhesive materials that decompose at other temperatures are within the contemplated scope of disclosure. A layer of passivation material (not shown) may optionally be formed on the adhesive layer.

The lower RDL structure 120A may be formed by alternately forming the plurality of dielectric layers 12 and plurality of redistribution layers 12a on the first carrier substrate 1. As illustrated in FIG. 5B, the formation of the redistribution layers 12a may include the formation of the lower RDL structure 302 of the guard ring 300.

Each dielectric layer 12 may each be formed, for example, by depositing (e.g., by chemical vapor deposition (CVD), physical vapor deposition (PVD) or other suitable deposition technique) a layer of dielectric polymer material such as polyimide (PI), benzocyclobutene (BCB), or polybenzobisoxazole (PBO). Other suitable materials are within the contemplated scope of disclosure. The thickness of the layer of dielectric polymer material may be in a range from 4 microns to 60 microns, although lesser and greater thicknesses may also be used. The dielectric layer 12 may then be patterned by a photolithographic process to form via holes in the dielectric layer 12. The photolithographic process may include forming a patterned photoresist mask (not shown) on the layer of dielectric material, and etching (e.g., wet etching, dry etching, etc.) the exposed upper surface of the dielectric material through openings in the photoresist mask. The photoresist mask may be subsequently removed by ashing, dissolving the photoresist mask or by consuming the photoresist mask during the etch process.

A redistribution layer 12a (e.g., metal traces and metal vias) may be formed on the dielectric layer 12. The redistribution layer 12a may be formed, for example, by depositing (e.g., by CVD, PVD or other suitable deposition technique) one or more layers of metal material such as copper, aluminum, nickel, titanium, a combination thereof or other suitable metals, on the dielectric layer 12 and in the vias holes formed by patterning the dielectric layer 12. The redistribution layer 12a may then be patterned by a photolithographic process. The photolithographic process may include forming a patterned photoresist mask (not shown) on the layer of metal material, and etching (e.g., wet etching, dry etching, etc.) the exposed upper surface of the metal material through openings in the photoresist mask. The photoresist mask may be subsequently removed by ashing, dissolving the photoresist mask or by consuming the photoresist mask during the etch process.

The bonding pads 125 may be formed on the uppermost dielectric layer 13. As illustrated in FIG. 5B, the formation of the bonding pads 125 may include the formation of the upper bonding pad 125 (e.g., annular-shaped upper bonding pad) of the lower via portion 304 of the guard ring 300 (e.g., see FIGS. 4A-4C). The upper bonding pads 125 may include a metallic material that may be bonded to a solder material. The upper bonding pads 125 may be formed by depositing (e.g., by CVD, PVD or other suitable deposition technique) one or more metal layers including a metal, metal alloys, and/or other metal-containing compounds (e.g., Cu, Al, Mo, Co, Ru, W, TiN, TaN, WN, etc.). The metal layer may then be patterned by a photolithographic process to form the upper bonding pads 125. The photolithographic process may include forming a patterned photoresist mask (not shown) on the metallic material, and etching (e.g., wet etching, dry etching, etc.) the exposed upper surface of the metallic material through openings in the photoresist mask. The photoresist mask may be subsequently removed by ashing, dissolving the photoresist mask or by consuming the photoresist mask during the etch process.

FIG. 5C is a vertical cross-sectional view of an intermediate structure including the TIVs 202 according to one or more embodiments. The TIVs 202 may be formed in one or more electroplating processes. As illustrated in FIG. 5C, the lower via portion 304 of the guard ring 300 may be formed in the same process and using the same materials as the TIVs 202. That is, in at least one embodiment, the lower via portion 304 may be constituted at least in part by a TIV 202.

In one or more embodiments, a seed layer (not shown) may be formed on the upper bonding pads 125. A metal material may then be electroplated on the seed layer to form the TIVs 202. In at least one embodiment, the TIVs 202 may be formed to have a thickness greater than 120 μm. In at least one embodiment, the TIVs 202 may be formed to have a height greater than 120 μm and a pitch of at least 80 μm. The metal material for electroplating may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

FIG. 5D is a vertical cross-sectional view of an intermediate structure including the interconnect die 201 mounted on the lower RDL structure 120A according to one or more embodiments. In at least one embodiment, the interconnect die 201 attached to the carrier 10 may be positioned over the corresponding upper bonding pads 125 on the lower RDL structure 120A using an electromechanical pick-and-place (PNP) machine. The interconnect die 201 may be oriented so that the second polymer layer 22 faces the corresponding upper bonding pads 125. The interconnect die 201 may then be lowered onto the corresponding upper bonding pads 125 using the PNP machine.

A direct bonding process may then be performed in order to form a microbump polymer direct bond joint between the interconnect die 201 and the corresponding upper bonding pads 125. The direct bonding process may form the direct bond to include a dielectric-dielectric bond between the first polymer layer 21 and the second polymer layer 22 around the upper bonding pads 125. The direct bonding process may also form the direct bond to include a metal-metal bond between the microbumps 28 (e.g., the solder caps of the microbumps 28) and the upper bonding pads 125.

FIG. 5E is a vertical cross-sectional view of an intermediate structure including the lower molding material layer 127 according to one or more embodiments. After the interconnect die 201 is placed on the lower RDL structure 120A, the carrier 10 may be removed from the interconnect die 201. The carrier 10 may be removed, for example, by laser debonding, thermal release, chemical debonding, etc.

The lower molding material layer 127 may then be formed by a specialized molding process (e.g., A3+ molding process). The molding process may include, for example, preparing the molding compound (e.g., e.g., by mixing resin, hardener, fillers, and additives) and injecting (or depositing by spray coating, spin coating or other suitable method) the molding compound into a mold cavity around the interconnect die 201. The molding compound may include an epoxy polymer material (e.g., an epoxy molding compound (EMC)). In at least one embodiment, the molding compound may be formed on the first carrier substrate 1 and fill in the gap between the interconnect die 201 and the TIVs 202. The molding compound may encapsulate (e.g., in the x-direction, y-direction and z-direction) the interconnect die 201. The molding process may further include curing the mold compound to achieve desired mechanical and thermal properties, and post-mold processing such as trimming, testing, etc.

The lower molding material layer 127 may be formed initially to have a thickness greater than a height of the interconnect die 201. In particular, the lower molding material layer 127 may be initially formed to have a thickness greater than a height of the third polymer layer 27 and the plurality of frontside metal vias 27a. In at least one embodiment, the lower molding material layer 127 may be initially formed to have a thickness in a range from about 170 μm to 210 μm (e.g., about 190 μm). The lower molding material layer 127 may then be allowed to cure.

After the lower molding material layer 127 has cured, a mechanical grinding process may be performed on the lower molding material layer 127. The mechanical grinding process may be performed until an upper surface of the TIVs 202, an upper surface of the lower via portion 304 and an upper surface of the frontside metal vias 27a is exposed. In at least one embodiment, the mechanical grinding process may be performed until a thickness of the lower molded portion 120B is in a range from 40 μm to 120 μm (e.g., about 70 μm to 90 μm). This may complete the formation of the lower molded portion 120B.

FIG. 5F is a vertical cross-sectional view of an intermediate structure including the upper RDL structure 120C according to one or more embodiments. After the lower molded portion 120B is formed, the upper RDL structure 120C may be formed on the lower molded portion 120B. The upper RDL structure 120C may be formed in a manner substantially similar to the manner of forming the lower RDL structure 120A (e.g., see FIG. 5B and associated text). The forming of the upper RDL structure 120C may include forming the bonding pads 214 on the uppermost dielectric layer 13 of the upper RDL structure 120C. The bonding pads 214 may be formed in a manner similar to the manner of forming the upper bonding pads 125 on the lower RDL structure 120A. The bonding pads 214 may include one or more underbump metallization layers (UBMLs).

FIG. 5G is a vertical cross-sectional view of an intermediate structure including the semiconductor dies 140 on the upper RDL structure 120C according to one or more embodiments. The HBM die 142 and the I/O die 143 may be attached to the upper RDL structure 120C by microbumps 128. The microbumps 128 may be formed to connect the bonding pads 214 to the die bonding pads 145 in the HBM die 142 and the I/O die 143.

In at least one embodiment, the microbumps 128 may include a two-dimensional array of microbumps 128. The HBM die 142 and I/O die 143 may be attached to the bonding pads 214 by C2 bonding, (e.g., solder bonding). The lower portion of the microbumps 128 (e.g., copper post and additional metal layers) may be formed on the bonding pads 214. The upper portion of the microbumps 128 (e.g., copper post and additional metal layers) may be formed on the die bonding pads 145. A solder layer may be formed, for example, on the lower portion of the microbumps 128.

The HBM die 142 and I/O die 143 may then be positioned over the upper RDL structure 120C using an electromechanical PNP machine. The upper portion of the microbumps 128 on the HBM die 142 and I/O die 143 may be substantially aligned with the lower portion of the microbumps 128 on the upper RDL structure 120C. A C2 bonding process that reflows the solder layer may then be performed to create a solder joint between the upper portion of the microbumps 128 and lower portion of the microbumps 128.

The SoC die 141 may be attached to the upper RDL structure 120C by a process similar to the process of mounting the interconnect die 201 on the lower RDL structure 120C. In particular, the SoC die 141 may be positioned over the corresponding bonding pads 214 on the upper RDL structure 120C using an electromechanical PNP machine. The SoC die 141 may be oriented so that the polymer layer 222 faces the corresponding bonding pads 214. The SoC die 141 may then be lowered onto the corresponding bonding pads 214 using the PNP machine.

A direct bonding process may then be performed in order to form a microbump polymer direct bond joint between the first semiconductor die 141 and the corresponding bonding pads 214. The direct bonding process may form the direct bond to include a dielectric-dielectric bond between the die polymer layer 221 and the polymer layer 222 around the bonding pads 214. The direct bonding process may also form the direct bond to include a metal-metal bond between the microbumps 228 (e.g., the solder caps of the microbumps 228) and the bonding pads 214.

FIG. 5H is a vertical cross-sectional view of an intermediate structure including the semiconductor die underfill layer 129 according to one or more embodiments. The semiconductor die underfill layer 129 may be applied by depositing and/or injecting an epoxy-based polymeric material onto the upper RDL structure 120C. The epoxy-based polymeric material may be applied on the upper RDL structure 120C so as to be formed under the HBM die 142 and the I/O die 143 and around the microbumps 128. The semiconductor die underfill layer 129 may be applied to the HBM die 142 and the I/O die 143 separately as illustrated in FIG. 5H. Alternatively, the semiconductor die underfill layer 129 may be applied to the HBM die 142 together with the I/O die 143 so that the semiconductor die underfill layer 129 is continuously formed between the HBM die 142 and the I/O die 143. In at least one embodiment, the epoxy-based polymeric material may fill substantially all of the gaps between the HBM die 142 and the upper RDL structure 120C and the gaps between the I/O die 143 and the upper RDL structure 120C. The semiconductor die underfill layer 129 may then be cured, for example, in a box oven for about 90 minutes at about 150° C. to provide the semiconductor die underfill layer 129 with a sufficient stiffness and mechanical strength.

FIG. 5I is a vertical cross-sectional view of an intermediate structure including the upper molding material layer 227 according to one or more embodiments. The upper molding material layer 227 may be formed by dispensing a liquid molding material (e.g., EMC, epoxy molding material, A7 molding compound, etc.) onto the intermediate structure of FIG. 5H by a suitable dispensing tool. The upper molding material layer 227 may be dispensed onto the intermediate structure to have a height greater than the height of the upper surface 140a of the semiconductor dies 140. The semiconductor dies 140 may have a thickness, for example, in a range of about 400 μm to 1000 μm (e.g., about 692 μm).

In at least one embodiment, a dispensing of the molding material may be automated. In particular, various aspects of the dispensing process may be computer-controlled by a control system (e.g., electronic control system; central processing unit (CPU)). In at least one embodiment, a beginning of the dispensing of the molding material, a flow rate of the dispensing of the molding material, and a stopping of the dispensing of the molding material may be controlled by the control system. The control system may be programmed, for example, to dispense a predetermined amount of the molding material based on various input parameters. The input parameters may include, for example, a volume of the space around the upper RDL structure 120C, sizes of the semiconductor dies 140, etc.

In at least one embodiment, the molding material of the upper molding material layer 227 may include a capillary material (e.g., capillary underfill type material). The molding material may have a low viscosity. In particular, the viscosity may be less than about 5,000 cP at 10 rpm. In at least one embodiment, the molding material may include a low-viscosity suspension of thermally conductive material (e.g., metal, metal oxide) in prepolymer. The low viscosity may help to facilitate transport of the molding material around the semiconductor dies 140. The low viscosity may also help to avoid the formation of voids in the upper molding material layer 227. In at least one embodiment, the upper molding material layer 227 may be substantially free of voids.

After the upper molding material layer 227 has been adequately cured, the upper molding material layer 227 may be planarized so as to make the upper surface of the upper molding material layer 227 to be substantially coplanar with the semiconductor die upper surface 140a. The upper molding material layer 227 may be planarized, for example, by mechanical grinding, chemical mechanical polishing (CMP) or other suitable planarization technique. This may complete formation of the upper molded portion 120D of the semiconductor die unit 120.

FIG. 5J is a vertical cross-sectional view of an intermediate structure including the BGA 180 according to one or more embodiments. The intermediate structure may be inverted, and the BGA 180 may be formed on the board-side surface of the lower RDL structure 120A. The BGA 180 may be formed, for example, by forming a plurality of C4 bumps 121 on the board-side surface of the semiconductor die unit 120. The C4 bumps 121 may be formed by forming a metal pillar (e.g., copper pillar) and a solder bump (e.g., SnAg solder bump) on the metal pillar. The BGA 180 may alternatively or additionally include a plurality of solder balls (not shown).

FIG. 5K is a vertical cross-sectional view of an intermediate structure including the fastening holes 102 in the semiconductor structure 100 according to one or more embodiments. As illustrated in FIG. 5K, the fastening holes 102 may be formed by a laser drill 575 (e.g., a high-precision laser system). The laser drill 575 may include, for example, an ultraviolet (UV) laser having a fine focus and causing minimal thermal damage to surrounding material. The UV laser may include an excimer laser or Nd: YAG laser operating in UV wavelengths. The laser drill 575 may emit a laser beam 580 shaped and focused (e.g., small diameter with clean edges) to match the dimensions of the fastening hole 102. The laser drill 575 may also include a pulsed laser which may allow controlled ablation of the material around the fastening hole without causing excessive heat buildup or damage to underlying structures.

In performing the laser drilling process, the laser beam 580 (e.g., laser energy) may be directed at the target location, where it rapidly heats and vaporizes the material of the semiconductor structure 100 (e.g., upper molding material layer 227, dielectric layers 13, lower molding material layer 127 and dielectric layers 12) through photothermal and photochemical ablation. The laser beam 580 may remove material layer by layer, ensuring precision and preventing damage to the material surrounding the fastening hole 102. The laser drill 575 may also provide for real-time monitoring (e.g., through cameras or sensors) to ensure accuracy and depth control. Other suitable methods of forming the fastening holes 102 are within the contemplated scope of disclosure. After the forming of the fastening holes 102, the formation of the semiconductor structure 100 may be complete.

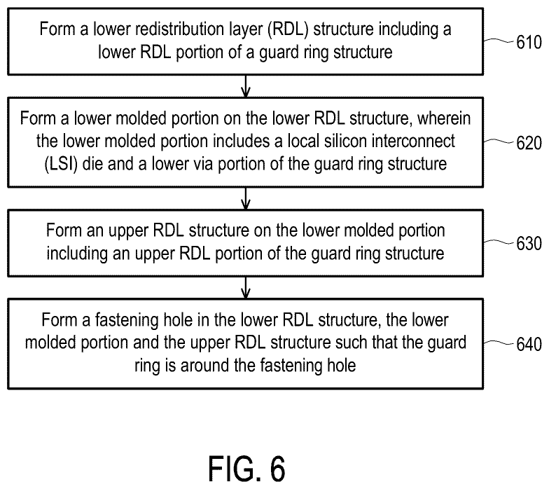

FIG. 6 is a flow chart illustrating a method of making the semiconductor structure 100 according to one or more embodiments. Step 610 includes forming a lower redistribution layer (RDL) structure including a lower RDL portion of a guard ring structure. Step 620 includes forming a lower molded portion on the lower RDL structure, wherein the lower molded portion includes an interconnect die and a lower via portion of the guard ring structure. Step 630 includes forming an upper RDL structure on the lower molded portion including an upper RDL portion of the guard ring structure. Step 640 includes forming a fastening hole in the lower RDL structure, the lower molded portion and the upper RDL structure such that the guard ring is around the fastening hole.

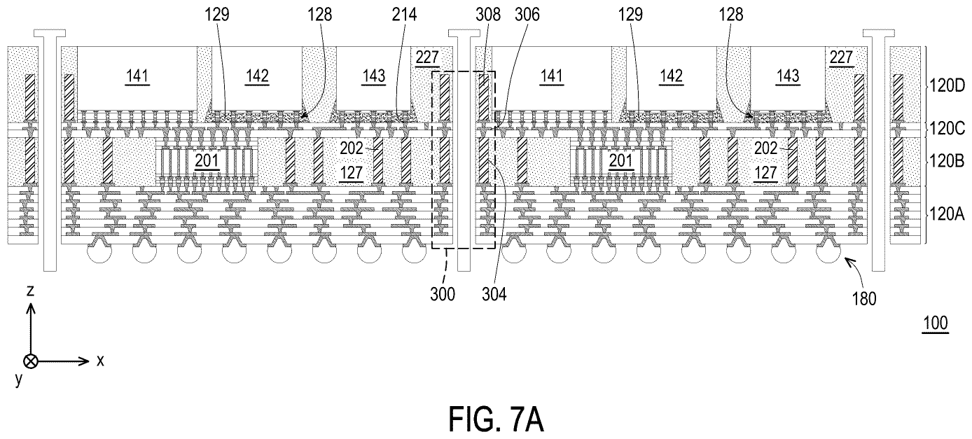

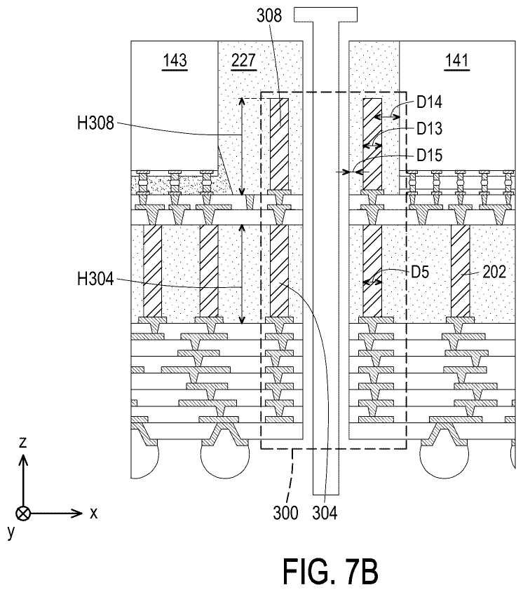

FIG. 7A is a vertical cross-sectional view of the semiconductor structure 100 including the guard ring 300 having the first alternative configuration according to one or more embodiments. FIG. 7B is a detailed vertical cross-sectional view of the guard ring 300 having the first alternative configuration according to one or more embodiments.

As illustrated in FIG. 7A, the guard ring 300 having the first alternative configuration may be substantially similar to the semiconductor structure 100 in FIG. 3D. However, the guard ring 300 having the first alternative configuration may include an upper via portion 308 in the upper molded portion 120D. The upper via portion 308 may have a structure substantially similar to the lower via portion 304. The upper via portion 308 may be substantially aligned with the lower via portion 304 in the z-direction. The upper via portion 308 may also be substantially aligned in the z-direction with the upper RDL portion 306 (e.g., the redistribution layer 13a of the upper RDL structure 120C).

As illustrated in FIG. 7B, the upper via portion 304 may include a metal via (e.g., similar to a TIV 202 in the lower molded portion 120B) on a bonding pad 214. In at least one embodiment, a height H308 of the upper via portion 308 (including the bonding pad 214) may be greater than a height H304 of the lower via portion 304 (including the upper bonding pad 125). In at least one embodiment, the height H308 of the upper via portion 308 may be in a range from 60 μm to 150 μm (e.g., about 90 μm to 120 μm).

The upper via portion 308 may have a width D13 substantially the same as the width D5 of the lower via portion 304 of the guard ring 300. In at least one embodiment, the width D13 of the upper via portion 308 may be in a range from 50 μm to 300 μm (e.g., about 120 μm to 200 μm). The upper via portion 308 may be separated from the semiconductor dies 140 in the upper molded portion 120D by a distance D14 greater than 1.0 mm. The upper via portion 308 may be separated from the fastening hole 102 by a distance D15 in a range from 50 μm to 200 μm (e.g., about 100 μm to 150 μm).

The upper via portion 308 may have a structure in a top-down view substantially similar to the top-down view of the lower via portion 304 in FIGS. 4B and 4C. In particular, the bonding pad 214 of the upper via portion 308 may include an annular-shaped bonding pad 214 formed around the fastening hole 102. The upper via portion 308 may include a plurality of metal vias (similar to metal vias 304a in FIGS. 4A and 4B) on the annular-shaped bonding pad 214 and arranged in a ring around the fastening hole 102.

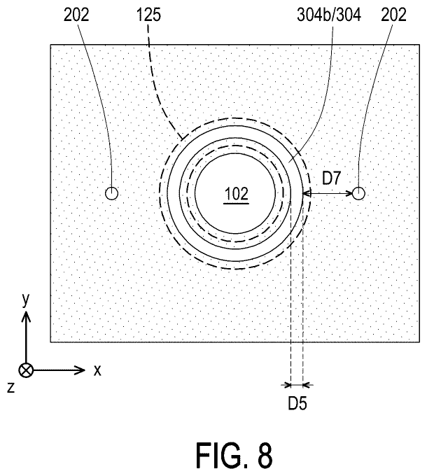

FIG. 8 is a top-down view of the guard ring 300 having a second alternative configuration according to one or more embodiments. The view in FIG. 8 is along line C-C′ in FIG. 4A.

As illustrated in FIG. 8, the guard ring 300 having the second alternative configuration may have a substantially similar to the guard ring 300 in FIGS. 4A-4B. However, in the second alternative configuration, the lower via portion 304 may include an annular-shaped metal via 304b on the upper bonding pad 125 instead of the plurality of metal vias 304a. The annular-shaped metal via 304b may be formed continuously around the fastening hole 102. The annular-shaped metal via 304b may have the width D5. The annular-shaped metal via 304b may be concentrically formed with the fastening hole 102. The annular-shaped metal via 304b may be concentrically formed with the upper bonding pad 125 of the lower via portion 304. The annular-shaped metal via 304b may also be substantially centered on the upper bonding pad 125.

It should be noted that in the second alternative configuration the upper via portion 308 may also have the configuration illustrated in FIG. 8. In particular, the upper via portion 308 may include an annular-shaped metal via on the upper bonding pad 214 instead of a plurality of metal vias.

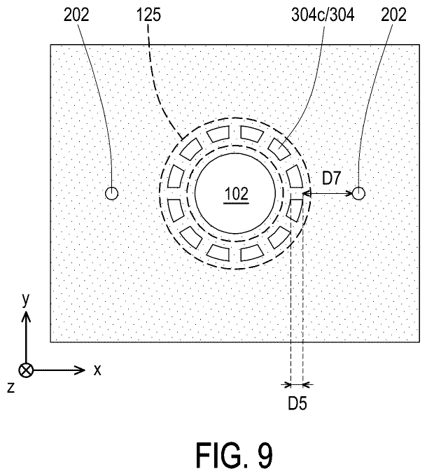

FIG. 9 is a top-down view of the guard ring 300 having a third alternative configuration according to one or more embodiments. The view in FIG. 9 is also along line C-C′ in FIG. 4A.

As illustrated in FIG. 9, the guard ring 300 having the third alternative configuration may have a substantially similar to the guard ring 300 having the second alternative configuration in FIG. 8. However, in the third alternative configuration, the lower via portion 304 may include a segmented annular-shaped metal via 304c on the upper bonding pad 125 instead of the annular-shaped metal via 304b in FIG. 8. The segmented annular-shaped metal via 304c may be formed in segments around the fastening hole 102. The area of the segments in the segmented annular-shaped metal via 304c may be in a range from 50% to 90% of the continuously formed annular-shaped metal via 304b in FIG. 8.

The segmented annular-shaped metal via 304c may also have the width D5. The segmented annular-shaped metal via 304c may also be concentrically formed with the fastening hole 102. The segmented annular-shaped metal via 304c may also be concentrically formed with the upper bonding pad 125 of the lower via portion 304. The segmented annular-shaped metal via 304c may also be substantially centered on the upper bonding pad 125.

It should be noted that in the third alternative configuration the upper via portion 308 may also have the configuration illustrated in FIG. 8. In particular, the upper via portion 308 may include an annular-shaped metal via on the upper bonding pad 214 instead of a plurality of metal vias.

It should further be noted that the configuration of the upper via portion 308 may be different from the configuration of the lower via portion 304. Thus, for example, the semiconductor structure 100 may have the upper via portion 308 with the configuration illustrated in FIG. 4B and the lower via portion 304 with the configuration in FIG. 8, the semiconductor structure 100 may have the upper via portion 308 with the configuration illustrated in FIG. 9 and the lower via portion 304 with the configuration in FIG. 4B, and so on.

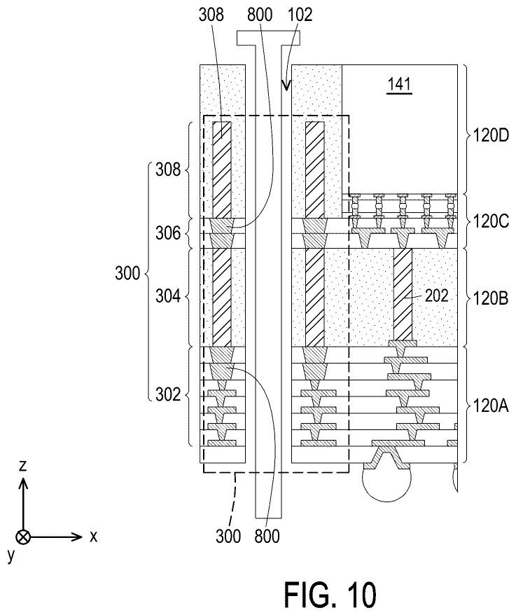

FIG. 10 is a top-down view of the guard ring 300 having a fourth alternative configuration according to one or more embodiments. As illustrated in FIG. 10, the guard ring 300 having the fourth alternative configuration may be substantially similar to the guard ring 300 having the first alternative configuration in FIG. 7B. However, in the guard ring 300 having the fourth alternative configuration in FIG. 10, at least a portion of the lower RDL portion 302 and/or at least a portion of the upper RDL portion 308 may include one or more large vias 800. The large vias 800 in the lower RDL portion 302 may be formed of the same material as the redistribution layers 12a in the lower RDL structure 120A. The large vias 800 in the upper RDL portion 308 may be formed of the same material as the redistribution layers 13a in the upper RDL structure 120C. In at least one embodiment, the large vias 800 may have an annular shape formed around the fastening hole 102.

The large vias 800 may be substantially aligned in the z-direction. In particular, the large vias 800 in the lower RDL portion 302 may be substantially aligned with the lower via portion 304. The large vias 800 in the upper RDL portion 306 may be substantially aligned with the upper via portion 308.

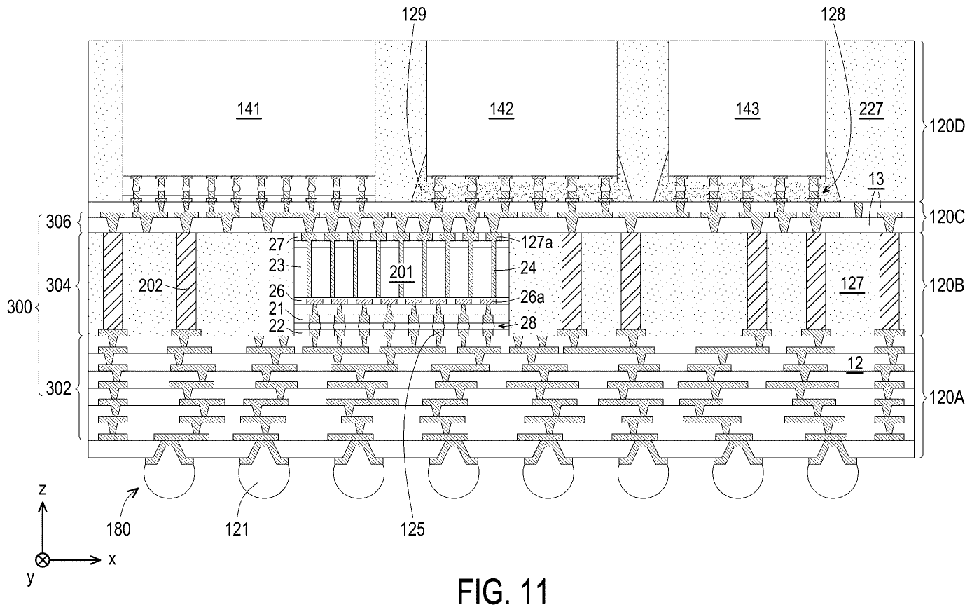

FIG. 11 is a vertical cross-sectional view of the semiconductor die unit 120 having a first alternative configuration according to one or more embodiments. As illustrated in FIG. 11, the semiconductor die unit 120 may have a configuration substantially similar to the configuration in FIG. 3C. However, in the first alternative configuration, the interconnect die 201 may have a frontside-to-backside (F2B) configuration (e.g., a frontside of the semiconductor dies 140 faces a backside of the interconnect die 201) instead of the frontside-to-frontside configuration (e.g., a frontside of the semiconductor dies 140 faces a frontside of the interconnect die 201) in FIG. 3C.

In the first alternative configuration, the interconnect dies 201 may be attached (e.g., electrically coupled) to the lower RDL structure 120A by a plurality of microbumps 28. The microbumps may be formed in a first polymer layer 21 of the interconnect dies 201. The microbumps 28 may include, for example, solder caps on metal pillars (e.g., copper pillars). The interconnect dies 201 may be attached to the lower RDL structure 120A by a direct bond (e.g., dual bond) including the microbumps 28 and the first polymer layer 21. The direct bond may include, for example, a dielectric-dielectric bond between the first polymer layer 21 and the second polymer layer 22 around the upper bonding pads 125. The direct bond may also include a metal-metal bond between the microbumps 28 (e.g., the solder caps of the microbumps 28) and the upper bonding pads 125.

In the first alternative configuration, the interconnect dies 201 may also include the bulk semiconductor region 23 including one or more through silicon vias (TSVs) 24. The interconnect dies 201 may also include the passivation layer 26 including a plurality of metal pads 26a (e.g., aluminum pads). The TSVs 24 may be electrically coupled to the microbumps 28 by the metal pads 26a. The interconnect dies 201 may also include an active region (not shown) that may include one or more active devices such as transistors, diodes, thyristors, etc. The active region may be adjacent the bulk semiconductor region and electrically coupled to the TSVs 24.

The interconnect dies 201 may also include a third polymer layer 27 including a plurality of backside metal vias 127a (e.g., backside copper vias). The backside metal vias 127a may be substantially similar to the frontside metal vias 27a in FIG. 3C. The backside metal vias 127a may also be electrically coupled to the TSVs 24.

Referring to FIGS. 1A-11, a semiconductor structure 100 may include a lower redistribution layer (RDL) structure, a lower molded portion 120B including an interconnect die 201 on the lower RDL structure 120A, an upper RDL structure 120C on the lower molded portion 120B, and a guard ring 300 including a lower RDL portion 302 in the lower RDL structure 120A, a lower via portion 304 in the lower molded portion 120B, and an upper RDL portion 306 in the upper RDL structure 120C.

In one embodiment, the guard ring 300 may be located around a fastening hole 102 in the lower RDL structure 120A, the lower molded portion 120B and the upper RDL structure 120C. In one embodiment, the lower via portion 304 may include at least one of a plurality of metal vias 304a arranged in a ring around the fastening hole 102, an annular-shaped metal via 304 around the fastening hole 102, or a segmented annular-shaped metal via 304c around the fastening hole 102. In one embodiment, the semiconductor structure 100 may further include an upper molded portion 120D including a plurality of semiconductor dies 140 on the upper RDL structure 120C, wherein the fastening hole 102 may be in the upper molded portion 120D and the guard ring 300 may further include an upper via portion 308 around the fastening hole 102. In one embodiment, a height H308 of the upper via portion 308 may be equal to or greater than a height H304 of the lower via portion 304. In one embodiment, the upper via portion 308 may include at least one of a plurality of metal vias 304a arranged in a ring around the fastening hole 102, an annular-shaped metal via around the fastening hole 102, or a segmented annular-shaped metal via around the fastening hole 102. In one embodiment, the upper via portion 308 may be electrically coupled to the lower via portion 304 by the upper RDL portion 306 in the upper RDL structure 120C. In one embodiment, the plurality of semiconductor dies 140 may include a plurality of semiconductor die units 120 comprising a plurality of corners, and the fastening hole 102 may include a plurality of fastening holes 102 at the plurality of corners of the plurality of semiconductor die units 120, respectively. In one embodiment, the plurality of semiconductor die units 120 are arranged in an array 150 including a plurality of rows and a plurality of columns and the plurality of fastening holes 102 are between the plurality of rows and the plurality of columns. In one embodiment, the plurality of semiconductor die units 120 may include a system on chip (SoC) die 141 and a plurality of high bandwidth memory (HBM) dies 142 on opposing sides of the SoC die 141 in a row direction, and the plurality of fastening holes 102 are adjacent the plurality of HBM dies 142. In one embodiment, the plurality of semiconductor die units 120 may further include a pair of input/output (I/O) dies 143 on opposing sides of the SoC die 141 in the row direction and between the plurality of HBM dies 142.

Referring again to FIGS. 1A-11, a method of making a semiconductor structure 100 may include forming a lower redistribution layer (RDL) structure 120A including a lower RDL portion 302 of a guard ring 300 structure, forming a lower molded portion 120B on the lower RDL structure 120A, wherein the lower molded portion 120B includes an interconnect die 201 and a lower via portion 304 of the guard ring 300 structure, forming an upper RDL structure 120C on the lower molded portion 120B including an upper RDL portion 306 of the guard ring 300 structure, and forming a fastening hole 102 in the lower RDL structure 120A, the lower molded portion 120B and the upper RDL structure 120C such that the guard ring 300 may be around the fastening hole 102.

In one embodiment, the forming of the lower molded portion 120B may include forming the lower via portion 304 such that the lower via portion 304 may include at least one of a plurality of metal vias 304a arranged in a ring around the fastening hole 102, an annular-shaped metal via around the fastening hole 102, or a segmented annular shaped metal via around the fastening hole 102. In one embodiment, the method may further include forming an upper molded portion 120D including a plurality of semiconductor dies 140 and an upper via portion 308 of the guard ring 300 on the upper RDL structure 120C, wherein the forming of the fastening hole 102 may include forming the fastening hole 102 in the upper molded portion 120D such that the upper via portion 308 of the guard ring 300 may be located around the fastening hole 102. In one embodiment, the forming of the upper molded portion 120D may include forming the upper via portion 308 such that a height H308 of the upper via portion 308 may be equal to or greater than a height H304 of the lower via portion 304. In one embodiment, the forming of the upper molded portion 120D may include forming the upper via portion 308 such that the upper via portion 308 may include at least one of a plurality of metal vias 304a arranged in a ring around the fastening hole 102, an annular-shaped metal via around the fastening hole 102, or a segmented annular-shaped metal via around the fastening hole 102. In one embodiment, the plurality of semiconductor dies 140 may include a plurality of semiconductor die units 120 comprising a plurality of corners, and the forming of the fastening hole 102 may include forming a plurality of fastening holes 102 at the plurality of corners of the plurality of semiconductor die units 120, respectively. In one embodiment, the plurality of semiconductor die units 120 may include a system on chip (SoC) die 141 and a plurality of high bandwidth memory (HBM) dies 142 on opposing sides of the SoC die 141 in a row direction, and the forming of the plurality of fastening holes 102 may include forming the plurality of fastening holes 102 adjacent the plurality of HBM dies 142.

Referring again to FIGS. 1A-11, a system on panel structure 400 may include a package substrate 410b (e.g., printed circuit board), a plurality of electronic modules 421, 422 on the package substrate 410b, a semiconductor structure 100 on a side of the package substrate 410b opposite the plurality of electronic modules 421, 422, wherein the semiconductor structure 100 includes a lower molded portion 120B including an interconnect die 201 and a lower via portion 304 of a guard ring 300, a thermal plate 405 on the semiconductor structure 100, and a fastening member 450 configured to fasten the thermal plate 405 to the semiconductor structure 100 and the package substrate 410b, wherein the lower via portion 304 of the guard ring 300 may be around the fastening member 450.

In one embodiment, the semiconductor structure 100 may further include a lower redistribution layer (RDL) structure 120A, wherein the lower molded portion 120B may be on the lower RDL structure 120A, and an upper RDL structure 120C on the lower molded portion 120B, wherein the guard ring 300 may further include a lower RDL portion 302 in the lower RDL structure 120A and an upper RDL portion 306 in the upper RDL structure 120C.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a lower redistribution layer (RDL) structure;
a lower molded portion including an interconnection die on the lower RDL structure;
an upper RDL structure on the lower molded portion; and
a guard ring comprising:
a lower RDL portion in the lower RDL structure;
a lower via portion in the lower molded portion; and
an upper RDL portion in the upper RDL structure.

2. The semiconductor structure of claim 1, wherein the guard ring is located around a fastening hole in the lower RDL structure, the lower molded portion and the upper RDL structure.

3. The semiconductor structure of claim 2, wherein the lower via portion comprises at least one of:
a plurality of metal vias arranged in a ring around the fastening hole;
an annular-shaped metal via around the fastening hole; or
a segmented annular-shaped metal via around the fastening hole.

4. The semiconductor structure of claim 2, further comprising:
an upper molded portion including a plurality of semiconductor dies on the upper RDL structure, wherein the fastening hole is in the upper molded portion and the guard ring further comprises an upper via portion around the fastening hole.

5. The semiconductor structure of claim 4, wherein a height of the upper via portion is equal to or greater than a height of the lower via portion.

6. The semiconductor structure of claim 4, wherein the upper via portion comprises at least one of:
a plurality of metal vias arranged in a ring around the fastening hole;
an annular-shaped metal via around the fastening hole; or
a segmented annular-shaped metal via around the fastening hole.

7. The semiconductor structure of claim 4, wherein the upper via portion is electrically coupled to the lower via portion by the upper RDL portion in the upper RDL structure.

8. The semiconductor structure of claim 4, wherein the plurality of semiconductor dies comprises a plurality of semiconductor die units comprising a plurality of corners, and the fastening hole comprises a plurality of fastening holes at the plurality of corners of the plurality of semiconductor die units, respectively.

9. The semiconductor structure of claim 8, wherein the plurality of semiconductor die units are arranged in an array including a plurality of rows and a plurality of columns and the plurality of fastening holes are between the plurality of rows and the plurality of columns.

10. The semiconductor structure of claim 9, wherein the plurality of semiconductor die units comprises a system on chip (SoC) die and a plurality of high bandwidth memory (HBM) dies on opposing sides of the SoC die in a row direction, and the plurality of fastening holes are adjacent the plurality of HBM dies.

11. The semiconductor structure of claim 10, wherein the plurality of semiconductor die units further comprises a pair of input/output (I/O) dies on opposing sides of the SoC die in the row direction and between the plurality of HBM dies.

12. A method of making a semiconductor structure, the method comprising:
forming a lower redistribution layer (RDL) structure including a lower RDL portion of a guard ring structure;
forming a lower molded portion on the lower RDL structure, wherein the lower molded portion includes an interconnect die and a lower via portion of the guard ring structure;
forming an upper RDL structure on the lower molded portion including an upper RDL portion of the guard ring structure; and
forming a fastening hole in the lower RDL structure, the lower molded portion and the upper RDL structure such that the guard ring is around the fastening hole.

13. The method of claim 12, wherein the forming of the lower molded portion comprises forming the lower via portion such that the lower via portion comprises at least one of:
a plurality of metal vias arranged in a ring around the fastening hole;
an annular-shaped metal via around the fastening hole; or
a segmented annular shaped metal via around the fastening hole.

14. The method of claim 12, further comprising:
forming an upper molded portion including a plurality of semiconductor dies and an upper via portion of the guard ring on the upper RDL structure, wherein the forming of the fastening hole comprises forming the fastening hole in the upper molded portion such that the upper via portion of the guard ring is located around the fastening hole.

15. The method of claim 14, wherein the forming of the upper molded portion comprises forming the upper via portion such that a height of the upper via portion is equal to or greater than a height of the lower via portion.

16. The method of claim 14, wherein the forming of the upper molded portion comprises forming the upper via portion such that the upper via portion comprises at least one of:
a plurality of metal vias arranged in a ring around the fastening hole;
an annular-shaped metal via around the fastening hole; or
a segmented annular-shaped metal via around the fastening hole.

17. The method of claim 14, wherein the plurality of semiconductor dies comprises a plurality of semiconductor die units comprising a plurality of corners, and the forming of the fastening hole comprises forming a plurality of fastening holes at the plurality of corners of the plurality of semiconductor die units, respectively.

18. The method of claim 17, wherein the plurality of semiconductor die units comprises a system on chip (SoC) die and a plurality of high bandwidth memory (HBM) dies on opposing sides of the SoC die in a row direction, and the forming of the plurality of fastening holes comprises forming the plurality of fastening holes adjacent the plurality of HBM dies.

19. A packaging structure, comprising:
a packaging substrate;
a plurality of electronic modules on the packaging substrate;
a semiconductor structure on a side of the packaging substrate opposite the plurality of electronic modules, wherein the semiconductor structure includes a lower molded portion including an interconnection die and a lower via portion of a guard ring;
a thermal plate on the semiconductor structure; and
a fastening member configured to fasten the thermal plate to the semiconductor structure and the packaging substrate, wherein the lower via portion of the guard ring is around the fastening member.

20. The packaging structure of claim 19, wherein the semiconductor structure further comprises:
a lower redistribution layer (RDL) structure, wherein the lower molded portion is on the lower RDL structure; and
an upper RDL structure on the lower molded portion, wherein the guard ring further comprises:
a lower RDL portion in the lower RDL structure; and
an upper RDL portion in the upper RDL structure.
